(19) United States
(12) Patent Application Publication
(10) Pub. No.: US 2009/0148688 A1
(43) Pub. Date: Jun. 11, 2009

(54) OPTICAL MATERIALS

(76) Inventors: Hiroshi Sasaki, Mito (JP); Makiko Sugibayashi, Chiba (JP); Kiyomi Nakamura, Hitachi (JP); Sadayuki Nishimura, Yokohama (JP); Koji Hirata, Yokohama (JP); Takanori Hisada, Yokohama (JP); Kei Adachi, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/026,651

(22) Filed: Feb. 6, 2008

(30) Foreign Application Priority Data
Feb. 7, 2007 (JP) 2007-028510

(51) Int. Cl. B32B 3/26; B32B 18/00; H01L 31/00; G03B 21/28; G02B 6/00; G02F 1/1335

(52) U.S. Cl. 428/315.9; 428/454; 136/252; 353/81; 353/20; 385/141; 362/97.2

(57) ABSTRACT

An optical material having a reflecting membrane, an enhanced reflecting membrane, or an anti-reflecting membrane formed with coating is provided. The optical material includes an optical material matrix, and a first inorganic compound layer and a second inorganic compound layer which are alternately stacked on the optical material matrix, wherein the first inorganic compound layer is formed of a titanium compound having a hydrolysable residue and oilophilic smectite and has a refractive index higher than the refractive index of the optical material matrix, and wherein the second inorganic compound layer includes silicon oxide and has a refractive index lower than the refractive index of the optical material matrix.

### FIELD OF THE INVENTION

The present invention relates to optical materials, for example, a reflecting membrane, an enhanced reflecting membrane, and an anti-reflecting membrane.

### BACKGROUND OF THE INVENTION

Titanium oxide is widely used in reflecting membranes (especially in dichroic mirrors), enhanced reflecting membranes, multi-layer anti-reflecting membranes for optics since it has a high reflective index.

Reflecting membranes formed by using inorganic oxides such as titanium oxide are more resistant to corrosion than metals such as silver, aluminum, and chromium, so that they have an advantage that the reflective index thereof does not reduce in a short time even near streets exposed to exhaust gas at a high concentration, near the sea, or in an area such as a hot spring where a corrosive gas exists at a high concentration.

A membrane containing titanium oxide is typically formed with vapor deposition in order to provide a highly uniform thickness. On the other hand, when a membrane containing titanium oxide is formed with coating, a binder made of an organic material is decomposed through photocatalysis and thus an inorganic material is desired. The membrane is formed by using titaniasol as a precursor of titanium oxide and performing heating to approximately 300 to 700° C. after the coating. A base material which is not resistant to this temperature is deformed due to the heat. If the base material is made from a plurality of members having different coefficients of thermal expansion, the resultant membrane has a problem such as cracking. While a membrane includes particles of titanium oxide dispersed in a resin curable at a low temperature is proposed, the particles of titanium oxide scatter incident light to provide lower light transmission in the base material. This reduces the transparency if the base material is transparent, blurs the color if the base material is colored, or frosts the surface if the base material has a shine.

For using reflecting membranes and enhanced reflecting membranes in optics, a low-refractive-index membrane is first formed on the surface of an optic, and then a membrane containing titanium oxide is formed thereon as a high-refractive-index membrane. The membrane is formed to have a thickness of λ/4n where λ represents the wavelength at which a higher reflective index is desired and n represents the refractive index of the membrane. To increase the reflective index, the low-refractive-index membrane and the high-refractive-index membrane are alternately stacked to provide a membrane having a high refractive index. As the number of stacked membranes increases, the maximum reflective index increases. However, a band in which a high reflective index is provided becomes narrower. Thus, a low-refractive-index membrane and a high-refractive-index membrane having different thicknesses are formed to allow a high reflective index in a wider band. As to anti-reflecting membranes, in contrast to the formation of the reflective membranes and enhanced reflecting membranes, a high-refractive-index membrane for a base material is first formed and then a low-refractive-index membrane is formed.

Patent Document 1: JP-A-2006-12317

### BRIEF SUMMARY OF THE INVENTION

The membrane containing titanium oxide, which is formed by using the above coating method requires treatment at a high temperature and cannot be used for a base material which is less resistant to heat. On the other hand, in the technique which does not involve heating, the transparency or the like is affected.

For using the reflecting membranes and enhanced reflecting membranes in optics, the membrane thickness is as extremely small as several tens to 110 nm in view of the visible region. To form the thin membrane transparently and uniformly with the coating, some contrivance of a coating material is necessary. Since titanium oxide cannot ensure transparency even in the form of particles, titaniasol which is a precursor needs to be used. In this case, the volume of titaniasol significantly contracts in response to heating. This is because an alkoxy group bonded to titaniasol is detached when titaniasol is changed into titanium oxide. In addition, titaniasol has a specific gravity of approximately 1, while titanium oxide has as large a specific gravity as 3.9. Consequently, when tetra-1-propyltitanate is used as titaniasol, for example, the resultant volume of titanium oxide corresponds to only approximately 7% of the titaniasol used. When tetra-n-butyltitanate is used, the resulting volume of titanium oxide corresponds to only approximately 6% of the titaniasol used. Thus, Hardening after the coating (change from titaniasol into titanium oxide) causes cracking to lose the transparency. For those reasons, the coating is considered in the fields of opaque membranes containing titanium oxide for the purpose of photocatalysis. The vapor deposition has been used to form a high-refractive-index membrane with titanium oxide for use in optics, and the coating has not been used at all therefor. To form a transparent high-refractive-index membrane for use in optics, it is necessary to use an inorganic binder which permits the volume contraction in the hardening.

In the case where high-refractive-index membranes and low-refractive-index membranes are stacked, a coating is applied on an already formed membrane after a second layer. As a result, the thickness, the refractive index and the like changes when the formed membrane expands or dissolves, thereby affecting optical characteristics. It is thus necessary to select composition so that the already formed membrane does not expand or dissolve when a coating applied to put another membrane thereon is contacted.

If a highly transparent membrane with a high refractive index can be formed by using a coating method, it is possible to form a membrane on a base material of a curved structure or a complicated structure having protrusions or the like. However, the conventional vapor deposition cannot achieve it. Also, the formation of a membrane on a large base material with the vapor deposition needs a large vacuum chamber suitable to form it. In this case, the high power consumption for pumping to provide a high vacuum therein is required. Thus, the conventional vapor deposition is not practical. However, if the coating method can be used, a membrane can be formed at normal pressure because of not using such a chamber or pumping, thereby allowing the membrane formation with low power.

Naturally, since a product from a high-refractive-index membrane (such as a dichroic mirror and a mirror having an enhanced reflecting membrane attached thereto) which conventionally has been formed with the vapor deposition can be also provided with a non-vacuum process, it is advantageous in terms of energy savings.

It is one object of the present invention to provide an optical material having a reflecting membrane, an enhanced reflecting membrane, or an anti-reflecting membrane formed by using a coating method.

Other object, feature and advantages of the invention will become apparent from the following description of the embodiments of the invention taken in conjunction with the accompanying drawings.

### BRIEF DESCRIPTION OF THE DRAWINGS

FIGS. 1(a) and 1(b) are a schematic diagram showing a section of a reflecting membrane according to the present invention;

FIG. 2 is a graph showing how the reflective index changes with the number of stacked high-refractive-index layers and low-refractive-index layers;

FIGS. 3(a) and 3(b) are a schematic diagram of a section of a reflecting membrane according to the present invention provided by stacking high-refractive-index layers and low-refractive-index layers having different thicknesses;

FIG. 4 is a graph showing the reflective index of the reflecting membrane according to the present invention provided by stacking high-refractive-index layers and low-refractive-index layers having different thicknesses;

FIG. 5 is a photograph of a section of a glass plate on which a high-refractive-index membrane and a low-refractive-index membrane used in the present invention are stacked;

FIG. 6 is a graph showing the reflective indexes of a transparent base material on which a single-layer anti-reflecting membrane is formed and of a transparent base material on which a two-layer anti-reflecting membrane is formed;

FIGS. 7(a) and 7(b) are graphs representing the presence strengths of elements in the low-refractive-index membrane;

FIGS. 8(a) to 8(e) are schematic diagrams showing sections of exemplary optical materials according to the present invention;

FIG. 9 is a schematic diagram showing an optical system of a liquid crystal projection-type display apparatus according to the present invention;

FIG. 10 is a schematic diagram showing a front projection-type display apparatus according to the present invention;

FIG. 11 is a schematic diagram showing a rear projection-type display apparatus according to the present invention;

FIGS. 12(a) and 12(b) are schematic diagrams showing display apparatuses with a free-curve mirror according to the present invention;

FIGS. 13(a) to 13(c) are schematic diagrams showing sections of the free-curve mirror according to the present invention;

FIG. 14 is a schematic diagram showing a light emitting device unit according to the present invention;

FIG. 15 is a schematic diagram showing a display apparatus according to the present invention;

FIG. 16 is a schematic diagram showing a section of a color filter for use in a display apparatus according to the present invention;

FIG. 17 is a schematic diagram showing a light conduction system according to the present invention;

FIG. 18 is a schematic diagram showing a vehicle lamp unit including a reflecting membrane according to the present invention;

FIG. 19 shows a greenhouse formed of an acrylic plate including an anti-reflecting membrane according to the present invention;

FIG. 20 is a schematic diagram showing a section of an optical recording medium including the reflecting membrane and the anti-reflecting membrane according to the present invention;

FIG. 21 is a schematic diagram showing a display apparatus according to the present invention viewed from above;

FIG. 22 is a schematic diagram showing a display apparatus according to the present invention viewed from above;

FIG. 23 is a schematic diagram showing the configuration of a cellular phone according to the present invention;

FIG. 24 is a schematic diagram showing the configuration of a cellular phone according to the present invention;

FIG. 25 is a schematic diagram showing a section of a plasma television according to the present invention;

FIG. 26 is a schematic diagram showing a section of a solar energy converting device according to the present invention;

FIG. 27 is a graph showing the reflective index of a glass plate on which the reflecting membrane according to the present invention is formed;

FIG. 28 is a graph showing the reflective index when the reflecting membrane according to the present invention is formed on a reflecting membrane made of aluminum;

FIG. 29 is a graph showing the reflective index of a glass plate on which the anti-reflecting membrane according to the present invention is formed;

FIG. 30 is a graph showing the reflective index of a glass plate on which the anti-reflecting membrane according to the present invention is formed;

FIG. 31 is a table showing the results of evaluation of liquid repellency on a surface of a substrate subjected to liquid-repellent treatment;

FIG. 32 is a table showing the results of evaluation of liquid repellency on a surface of a substrate subjected to liquid-repellent treatment;

FIG. 33 is a table showing the results of evaluation of liquid repellency on a surface of a substrate subjected to liquid-repellent treatment;

FIG. 34 is a table showing the results of evaluation of liquid repellency on a surface of a substrate subjected to liquid-repellent treatment;

FIG. 35 is a table showing the results of evaluation of liquid repellency on a surface of a substrate subjected to liquid-repellent treatment; and

FIG. 36 is a table showing the results of evaluation of liquid repellency on a surface of a substrate subjected to liquid-repellent treatment.

### DESCRIPTION OF REFERENCE NUMERALS

1, 22, 63 BASE MATERIAL
2, 17 LOW-REFRACTIVE-INDEX MEMBRANE
3, 18 HIGH-REFRACTIVE-INDEX MEMBRANE
15 CARBON LAYER
16, 111 GLASS PLATE
19 VOID
23, 69, 92 REFLECTING MEMBRANE
24 INCIDENT LIGHT
25 LIGHT SOURCE
26 FIRST REFLECTOR
27 SECOND REFLECTOR
28, 93, 112, 113 ANTI-REFLECTING MEMBRANE
29 INCIDENT LIGHT
30 EXIT LIGHT
31, 91 LAMP
32 REFLECTOR
33 CONCAVE LENS
34 FIRST LENS ARRAY
35 SECOND LENS ARRAY
36 POLARIZATION CONVERTER
37, 38, 39 DISPLAY DEVICE
40, 41, 42, 43 CONDENSER LENS
44 FIRST RELAY LENS
45 SECOND RELAY LENS
46, 47, 48, 49 MIRROR
50, 51 DICHROIC MIRROR
52 DICHROIC-CROSS-PRISM
53 PROJECTION LENS
54, 59 SCREEN
55, 57, 61 OPTICAL UNIT
56, 60, 108 HOUSING
58 BACK-FACE MIRROR
62 FREE-CURVE MIRROR
64 HARD LAYER
65 REFLECTING LAYER
66 LOW-REFRACTIVE-INDEX LAYER
67 SOIL-RESISTANT LAYER
68 HIGH-REFRACTIVE-INDEX LAYER
70 LIGHT-EMITTING DIODE CHIP
71 INSULATING LAYER
72 LEAD FRAME
73 HEAT-RADIATING SUBSTRATE
74 LIGHT EMITTING DEVICE UNIT
75 GROUP OF OPTICAL MATERIALS
76 NON-LIGHT-EMITTING DISPLAY PANEL
77 R FILTER
78 REFLECTING LAYER FOR REFLECTING LIGHT TRANSMITTED WITH G AND B
79 G FILTER
80 B FILTER
81 REFLECTING LAYER FOR TRANSMITTING G LIGHT AND REFLECTING LIGHT TRANSMITTED WITH R AND B
82 REFLECTING LAYER FOR TRANSMITTING B LIGHT AND REFLECTING LIGHT TRANSMITTED WITH R AND G
83 BLACK MATRIX
84 BUILDING
85 CURVED MIRROR
86 LIGHT-GUIDE TUBE
87 LIGHT CONDUCTION PART
88 LIGHT-EXIT PART
89 PROTECTING COVER
90 HOUSING
94 POLYCARBONATE SUBSTRATE
95 PROTECTING LAYER
96 RECORDING LAYER
97 MONITOR
98 SPACER
99 GLASS PLATE HAVING ANTI-REFLECTING MEMBRANE FORMED ON BOTH SIDES
100, 105 POLARIZER
101 TRANSPARENT ORGANIC RESIN
102 DISPLAY PART
103 ACYLIC PLATE HAVING ANTI-REFLECTING MEMBRANE ACCORDING TO THE PRESENT INVENTION FORMED THEREON
104 OPERATION PART
106, 110 GAP
107 RESIN FILLING LAYER
109 PANEL
114 GLASS SUBSTRATE
115 SURFACE ELECTRODE
116 UPPER PHOTON-ELECTRON CONVERTER LAYER
117 MIDDLE TRANSPORT ELECTRODE
118 BOTTOM PHOTON-ELECTRON CONVERTER LAYER
119 BACK ELECTRODE

### DETAILED DESCRIPTION OF THE INVENTION

The present applicants have found from investigations of various materials and methods for forming membranes that a membrane formed of a titanium compound having a hydrolysable residue and oilophilic smectite is transparent and has a high refractive index, thereby completing the present invention. The applicants have also found that this membrane and the low-refractive-index membrane made of silicon oxide are alternately stacked to provide a mirror, an enhanced reflecting membrane, an anti-reflecting membrane and the like.

Specifically, the present invention provides an optical material including an optical material matrix, a first inorganic compound layer and a second inorganic compound layer which are alternately stacked on the optical material matrix, wherein the first inorganic compound layer is formed of a titanium compound having a hydrolysable residue and an oilophilic smectite and has a refractive index higher than the refractive index of the optical material matrix, and wherein the second inorganic compound layer includes silicon oxide and having a refractive index lower than the refractive index of the optical material matrix.

When the first inorganic compound layer having the refractive index higher than that of the optical material matrix is formed immediately above the optical material matrix, the resulting optical material serves as an anti-reflecting membrane. When the second inorganic compound layer having the refractive index lower than that of the optical material matrix is formed just above the optical material matrix, the resulting optical material serves as a reflecting membrane or an enhanced reflecting membrane.

### ADVANTAGES OF THE INVENTION

According to the present invention, the optical material having a reflecting membrane, an enhanced reflecting membrane, and an anti-reflecting membrane formed by using a coating method are provided.

First, outlines of the present invention will be described. However, the present invention is not limited to the specific examples and various changes and modification may be made without departing from the spirit and scope of the present invention.

In the present invention, it is technically important to form a high-reflective-index membrane by applying a coating to a base material, and then by performing heating thereof to provide a high-refractive-index membrane and a low-refractive-index membrane.

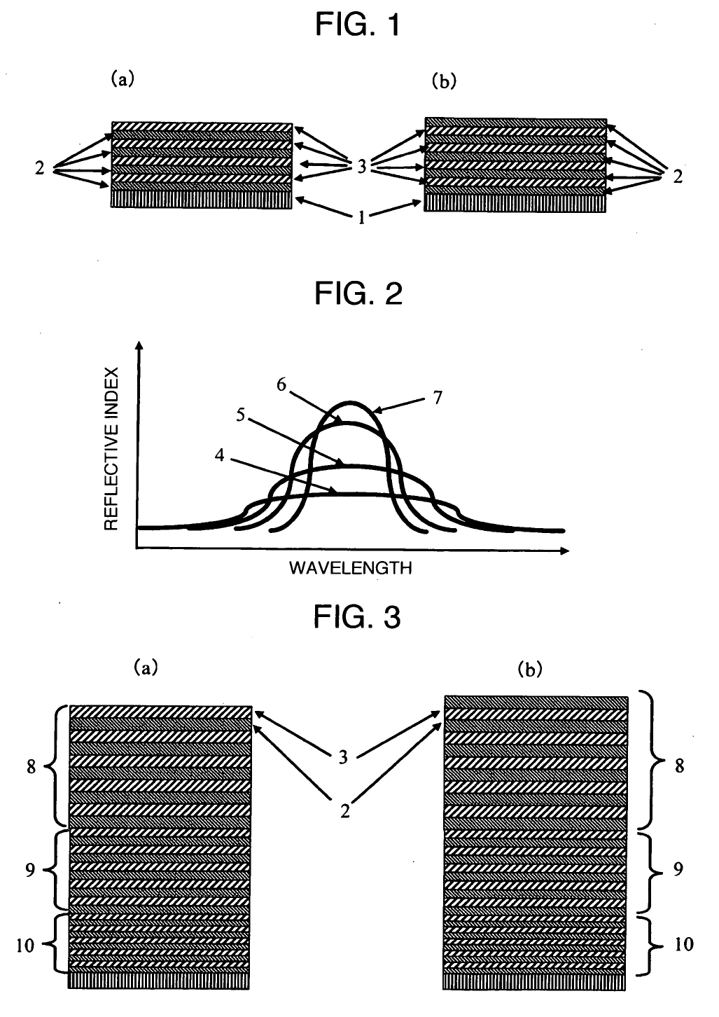

FIG. 1 is a schematic diagram of a section of a reflecting membrane according to the present invention. FIG. 2 is a graph showing how the reflective index changes with the number of stacked high-refractive-index layers and low-refractive-index layers, where the vertical axis represents the reflective index and the horizontal axis represents the wavelength. As shown in FIG. 1, low-refractive-index membranes 2 and high-refractive-index membranes 3 are stacked on a base material 1. As shown in FIG. 2, the maximum reflective index increases as the number of stacked membranes increases from a curve 4 representing two stacked layers (a single low-refractive-index membrane and a single high-refractive-index membrane), to a curve 5 representing four stacked layers (in the order of a low-refractive-index membrane, a high-refractive-index membrane, a low-refractive-index membrane, and a high-refractive-index membrane), and a curve 6 representing six stacked layers, and a curve 7 representing eight stacked layers. As the number of stacked membranes is larger, the wavelength region (band) with a high reflective index becomes narrower and the reflective index in a particular wavelength region increases. This technique can be utilized for a dichroic mirror. The particular wavelength region is determined by the thickness of the high-refractive-index membrane and the low-refractive-index membrane. The membrane is formed to satisfy the following expression:

T=λ/(4n)

where T represents the membrane thickness, λ represents the wavelength at which the maximum reflective index is shown, and n represents the refractive index of the low-refractive-index membrane or the high-refractive-index membrane.

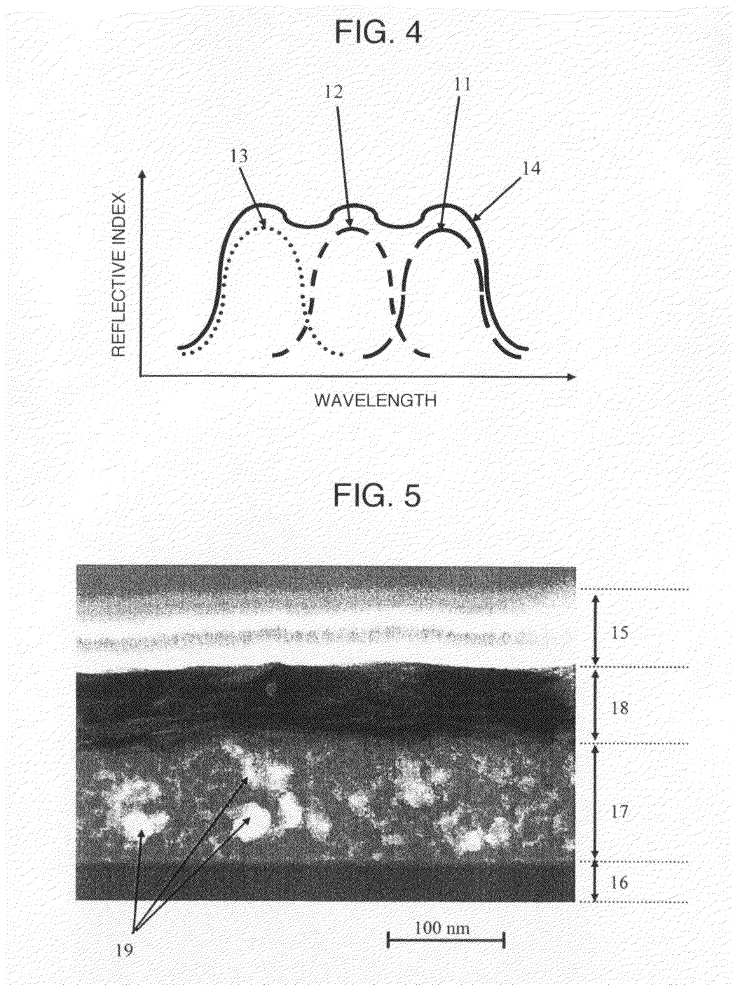

While an increased number of stacked membranes reduces the band, the band can be widened by stacking low-refractive-index membranes and high-refractive-index membranes having different thicknesses. FIG. 3 is a schematic diagram of a section of a reflecting membrane according to the present invention provided by stacking high-refractive-index layers and low-refractive-index layers having different thicknesses. FIG. 4 is a graph showing the reflective index of the reflecting membrane according to the present invention provided by stacking high-refractive-index layers and low-refractive-index layers having different thicknesses, where vertical axis represents the reflective index and the horizontal axis represents the wavelength. As shown in FIG. 3, the low-refractive-index membranes and the high-refractive-index membranes having different thicknesses are stacked to form a reflecting layer 8 for a long wavelength, a reflecting layer 9 for an intermediate wavelength, and a reflecting layer 10 for a short wavelength. As shown in FIG. 4, a reflective index 11 of the reflecting layer for the long wavelength, a reflective index 12 of the reflecting layer for the intermediate wavelength, and a reflective index 13 of the reflecting layer for the short wavelength are summed to a total reflective index 14 showing a high reflective index in a wide region. This provides a reflecting membrane for a wide band as a general mirror. In FIGS. 1(a) and 3(a), the high-refractive-index membrane is placed on the outermost layer, but the low-refractive-index membrane is preferably placed on the outermost layer in soil-resistant treatment, as described later. Thus, as shown in FIGS. 1(b) and 3(b), another low-refractive-index membrane is effectively placed thereon. The reflective index of the reflecting membrane according to the present invention hardly changes whether another low-refractive-index membrane is placed or not.

FIG. 5 shows a TEM photograph of a section of a glass plate on which a high-refractive-index membrane and a low-refractive-index membrane are stacked. While the photograph shows a carbon layer 15 on the high-refractive-index membrane, this layer 15 was formed only for preventing any break of the section in producing a sample of the section in measurement, and the present invention achieves the effects if the layer 15 does not exist. A low-refractive-index membrane 17 and a high-refractive-index membrane 18 are formed on a glass plate 16. Voids 19 are present in the low-refractive-index membrane 17. The voids are described later.

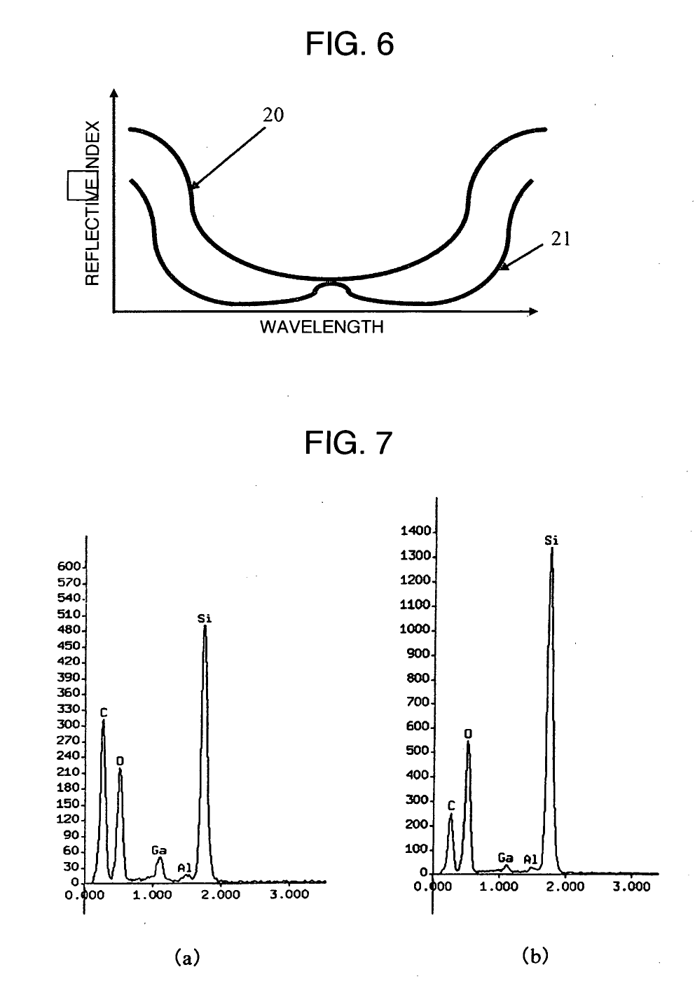

FIG. 6 is a graph showing a reflective index 20 in forming a single-layer anti-reflecting membrane and a reflective index 21 in forming a two-layer anti-reflecting membrane, where the vertical axis represents the reflective index and the horizontal axis represents the wavelength. The single-layer anti-reflecting membrane is formed of a low-refractive-index membrane. As seen from FIG. 6, as compared with the single-layer anti-reflecting membrane provided by firstly forming the low-refractive-index membrane on a base material, the two-layer anti-reflecting membrane provided by forming a high-refractive-index membrane on a base material and then by forming a low-refractive-index membrane thereon can achieve a lower reflective index in a wider band.

The formation of the abovementioned dichroic mirror, reflecting membrane with the wide band, and anti-reflecting membrane requires some detailed techniques as follows:

(A) Coating technique for forming a transparent high-refractive-index membrane: this is achieved by a coating material containing titaniasol and synthetic smectite, as later described;

(B) Coating technique for forming a transparent low-refractive-index membrane: this is provided by a coating material containing a hydrolytic silicon compound and particles of silicon oxide, as described later;

(C) Membrane composition and coating composition technique for stacking a plurality of the high-refractive-index membranes and the low-refractive-index membranes: this requires that the membranes formed with the coatings in (A) and (B) are resistant to coating solvents in (A) and (B);

(D) Technique for forming the high-refractive-index membrane and the low-refractive-index membrane with a thickness of several tens nm to a hundred and several tens nm: some contrivance is necessary for the method for applying the coating materials of (A) and (B). This is achieved by a coating method, as described later; and

(E) Low hardening temperature: a base material made of resin or the like and formed into a complicated shape is deformed at a high hardening temperature, and therefore the coating should be hardened at a low temperature. This is also achieved by use of a coating material of a composition, as described later.

First, a coating for forming the high-refractive-index membrane (coating for high-refractive-index membrane) and a coating for forming the low-refractive-index membrane (coating for low-refractive-index membrane) will be described. Then, a coating method, a hardening method and the like will be described.

### (1) Coating for High-Refractive-Index Membrane

The coating for high-refractive-index membrane is mainly formed of three components, that is, titaniasol for providing a high refractive index, oilophilic smectite as a binder serving as a supporter, and a solvent for diluting them in accordance with coating conditions. Besides, various additives such as a stabilizer for suppressing hydrolysis of titaniasol, particles for increasing the haze of the membrane, and a colorant for coloring the membrane are, if necessary, added thereto from the point of view of the intended uses.

Since titaniasol is more easily hydrolyzed when it is added at a higher concentration, the life of the coating material, that is, so-called a pot life is shortened. The refractive index, transparency, and the like depend on the addition ratio between a titaniasol serving as a solid material for forming the membrane and an oilophilic smectite. As titaniasol is added at a higher ratio, the refractive index is increased, but the roughness of the membrane tends to increase to reduce the transparency. The roughness, that is, the degree of roughing, is desirably 100 nm or less when it is determined by using the arithmetric mean deviation of the profile Ra. A roughness greater than that tends to reduce the transparency of the membrane in the visible region. The mixing ratio between titaniasol and oilophilic smectite depends on the structure of titaniasol. This is because the rate of titanium oxide is produced from titaniasol is different. In terms of the ratio between titanium oxide and oilophilic smectite, a 9:1 ratio between titanium oxide and oilophilic smectite provides a membrane having a refractive index of approximately 2. A higher ratio of titanium oxide than this is not preferable since the resultant optical thin membrane has insufficient functions such as an increased roughness of the surface and a reduced transmittance. On the other hand, a 1:1 ratio between titanium oxide and oilophilic smectite provides a membrane having a refractive index of approximately 1.6 and a pencil hardness of approximately H. A lower ratio of titanium oxide than this considerably reduces the membrane hardness. When titaniasol which is a precursor of titanium oxide is changed into titanium oxide, it forms cross-links with oilophilic smectite to increase the physical strength of the membrane. However, if the ratio of titanium oxide is reduced, fewer cross-links are formed to reduce the physical strength. Oilophilic smectite is a clayey material and the membrane formed only of oilophilic smectite is extremely fragile. Thus, the mixing ratio between a titaniasol and oilophilic smectite is preferably 50 to 90% of titanium oxide and 10 to 50% of oilophilic smectite in terms of the mixing ratio between titanium oxide and oilophilic smectite, and the refractive index of the high-refractive-index membrane in this case is 1.6 to 2.0.

### (i) Titaniasol

Titaniasol is formed of titanium binding to an alkoxysilane residue and is changed into titanium oxide through a dealcohol reaction proceeding with hydrolysis. During the process, it binds to some of elements of oilophilic smectite to make oilophilic smectite insoluble in an organic solvent. Titaniasol tends to be more hydrolyzed as it contains a higher percentage of titanium in the molecules. Thus, the use of titaniasol containing a higher percentage of titanium in the molecules tends to cause the resulting coating for the high-refractive-index membrane to have a shorter pot life.

Titaniasol which can be used in the present invention include compounds such as tetra-1-propoxytitanate, tetra-n-butoxytitanate, tetrakis (2-ethylhexyl) titanate, tetraheptadecaoxytitanate, tetrastearyloxytitanate, di-1-propoxybis (acetylacetonate) titanate, di-1-propoxybis (triethanolacetonate) titanate, di-n-butoxybis (triethanolacetonate) titanate, di-1-hydroxybis (carboxymethylmethoxy) titanate, and tetrakis (1-n-proxyl-2-ethylpropoxy) titanate.

### (ii) Binder

Titanium oxide formed from titaniasol shows photocatalysis due to anatase form of it. Since a binder of an organic compound such as acrylic resin, epoxy resin, or urethane resin is decomposed through the photocatalysis to cause peeling of the membrane, an appropriate material is the material made of an inorganic compound as a main raw material. In changing from titaniasol into titanium oxide, the volume is reduced to 10% or less. And this contraction may crack the membrane to reduce the transparency. To address this, a binder which prevents the decomposition from the photocatalysis and flexibly accommodates the volume contraction is desirable. In addition, when titaniasol is changed into titanium oxide, a desirable binder chemically binds to titanium oxide to disperse titanium oxide into the membrane at the molecular level, thereby increasing transparency of the membrane.

Synthetic smectite is one of the materials which satisfy those conditions. Smectite is made of an inorganic element and contains a hydroxyl residue which can react with titaniasol. For this reason, smectite can disperse a considerable percentage of titanium oxide into the membrane at the molecular level. In addition, the membrane of smectite has a structure of stacked layers at a nano level and has voids between the layers. The voids accommodate the volume variation (contraction) caused by the change of titaniasol into titanium oxide, so that the membrane is hardly cracked.

If titaniasol is stable in water to some degree, hydrophilic smectite can be used. However, most types of titaniasol tend to be hydrolyzed when it is in contact with water, and in forming the membrane, water may be repelled by the surface of the member due to a larger surface tension than a typical organic solvent, and thus the possibility that a flat membrane cannot be formed may occur. From the above two reasons, it is preferable to use smectite which is soluble in an organic solvent or diffusible favorably. In order to achieve them, an oilophilic residue is, for example, introduced into hydrophilic smectite (for example, hydrophilic smectite SWN, SWF, manufactured by COOP CHEMICAL CO., LTD. and smecton SA manufactured by KUNIMINE INDUSTRIES CO., LTD.). Hydrophilic smectite can be changed into oilophilic, for example by applying a silane coupling agent having an alkyl group (for example, hexatrimethoxysilane, decyltrimethoxysilane, and phenyltrimethoxysilane) to hydrophilic smectite. Originally oilophilic smectite may be used, for example oilophilic smectite SAN, SAN316, STN, SEN, and SPN manufactured by COOP CHEMICAL CO., LTD.

(iii) Additive Agent

A membrane including only oilophilic smectite as the binder has a poor physical strength and may be dissolved in various organic solvents. However, the formation of a chemical binding to titanium oxide increases the hardness of the membrane and makes the membrane insoluble or less soluble in organic solvents. Addition of particles of silicon oxide thereto tends to further improve the hardness of the membrane. This is because silicon oxide has a hydroxyl residue which can chemically bind to titanium oxide when titaniasol is changed into titanium oxide, and further has a higher hardness than smectite, so that the addition of silicon oxide can easily provide a membrane with a higher hardness compared with the case where the binder includes only smectite. The silicon oxide particles desirably have small diameters to ensure transparency. For spherical particles of silicon oxide, the average particle diameter is desirably 190 nm or less to prevent scattering of visible light (at wavelengths of 380 to 760 nm) incident on the membrane. An average diameter larger than this range causes scattering of incident light to visually make the membrane cloudy, which may lead to disadvantages in use for optics. For chain-shaped particles of silicon oxide, the chain desirably has a thickness of 190 nm or less for the same reason as described above. As the diameter of the silicon oxide particles is smaller, the transparency is higher. Thus, the average particle diameter is preferably 100 nm or less. The lower limit of the size of the silicon oxide particles in the present invention is approximately 9 nm in view of available particles, but a smaller size than this value causes no problem if the particles are favorably diffused in the membrane.

Silicon oxide particles used include aerosil manufactured by NIPPON AEROSIL CO., LTD. It is necessary to select particles having an average diameter of approximately several nm to 100 nm among them. For example, organosilicasol and Snowtex manufactured by NISSAN CHEMICAL INDUSTRIES are illustrated as a colloidal silica. These particles are highly hydrophilic since they have a number of hydroxyl residues on the surface. In addition, since they are dispersed in an organic solvent or water, they are easily dispersed in the coating material. A membrane formed of the particles as members is hydrophilic and has an extremely low resistance, specifically, approximately 1×10¹⁰ to 10×10¹⁰Ω. This value is very small and only from one-ten-thousandth to one-millionth of the resistances of glass, acrylic resin, polycarbonate resin, and polyethylene terephthalate (PET) resin, so that dirt including dust hardly attaches thereto. As a result, an optical material having the membrane according to the present invention on the outermost surface has an advantage that no dust attaches to the surface thereof for a long time period even in a dry room.

If the particles are insufficiently dispersed into the added coating material, the particles are flocculated into large secondary particles to visually make the membrane cloudy. To solve this problem, it is preferable to use a solvent which preferably disperses the silicon oxide particles, but such a solvent may not be used depending on the type of an optical material. In that case, a dispersant is added thereto. Specifically, a nonionic dispersant is preferable. Some of ionic dispersants are not preferable since they promote reaction of titaniasol into titanium oxide to shorten the pot life of the coating.

### (iv) Solvent

It is necessary to select a solvent which dissolves or favorably disperses titaniasol and oilophilic smectite. Since titaniasol is easily changed into titanium oxide when it is in contact with a solvent such as water, methanol, ethyleneglycol, and glycerin wherein the solvent has a hydroxyl residue in molecules and includes a small remaining portion except for the hydroxyl residue, the use of such a solvent for the coating tends to shorten the pot life. To prepare the coating having a longer pot life, it is necessary to select a solvent which does not or hardly promotes the reaction of titaniasol into titanium oxide. Since oilophilic smectite is not particularly modified due to the influence of a solvent. The solvent which suits titaniasol to be used as well as dissolves or favorably disperses oilophilic smectite can be used with no significant problems. Although having a hydroxyl residue in molecules, propanol and butanol are preferable as the solvent since they hardly promote the reaction of titaniasol into titanium oxide by the presence of a somewhat large remaining portion except for the hydroxyl residue. A solvent having aromatic ring such as benzene, toluene, and xylene is preferable. This is because they do not have any hydroxyl residue, and thus do not promote the reaction of titaniasol into titanium oxide. In addition, a halogen solvent such as dichloromethane and dichloroethane is preferable. This is because they do not have any hydroxyl residue, and thus do not promote the reaction of titaniasol into titanium oxide. A hydrocarbon solvent such as hexane and octane is preferable. This is because they do not have any hydroxyl residue, and thus do not promote the reaction of titaniasol into titanium oxide. A hydrocarbon solvent such as tetrahydrofuran and dioxane is preferable. This is because they do not have any hydroxyl residue, and thus do not promote the reaction of titaniasol into titanium oxide.

### (v) Membrane Forming Method

The high-refractive-index membrane for use in the present invention is formed through pretreatment of a base material, coating, and heating. While the pretreatment is performed on the base material in the description, the pretreatment is actually performed on the low-refractive-index membrane, not on the base material, if membrane formation is performed on the low-refractive-index membrane. In the membrane formation on the low-refractive-index membrane, a membrane of silicon oxide has high wettability, and thus does not require the pretreatment. However, the low-refractive-index membrane made of fluoric resin or the like which is described later may have insufficient wettability, and therefore the pretreatment is required.

### (a) Pretreatment

In the pretreatment, the base material is washed and the wettability of the base material is improved in order to uniformly attach the coating material thereto.

### 1. Washing of Base Material

The washing of the base material is performed by using a solvent, a washing agent or the like which can satisfactorily dissolve or remove soil attached to the base material. When the base material is made of resin, for example acryl or polycarbonate, an alcohol solvent such as methanol, ethanol, propanol, and butanol is more desirable than a solvent which dissolves the surface to produce clouding (such as tetrahydrofuran, dioxane, 2-butanone, and ethylacetate). When the base material is made of glass, the base material may be immersed in a basic solution (for example, a sodium hydroxide solution) to slightly etch the surface to remove soil together, and heating may also be preferably performed during the immersion to attain quick proceeding of the etching. However, the heating for a long time may cause the etching to proceed more than necessary to cloud the surface, so that it should be performed carefully.

### 2. Improvement in Wettability of Base Material

Since the improved wettability of the base material helps the uniform application of the coating material to reduce variations in the membrane thickness, excellent optical characteristics can be provided. Methods for improving the wettability of the base material include a method of modifying a surface with an apparatus such as a plasma irradiation apparatus and a method of chemically modifying a surface with an acid, a basic solution or the like.

Method of Modifying Surface with Apparatus

The method includes oxygen plasma irradiation, placement in an ozone atmosphere, and UV irradiation. In any case of them, active oxygen acts on the surface of the base material to produce a hydroxyl residue, a carboxyl residue or the like. Since these residues are hydrophilic, the surface on which these residues are produced has improved wettability to make it easy to provide a membrane having a uniform thickness with the coating. In the UV irradiation, the UV changes oxygen in the air into an active state to modify the surface, so that it can provide the effects similar to those of the oxygen plasma irradiation and the placement in an ozone atmosphere. The method also includes argon plasma. The wettability is also improved by the irradiation of argon plasma. In the case where the output from a high-frequency power of a plasma generating apparatus is the same, the irradiation period of argon plasma should be longer than that of oxygen plasma.

Method of Chemically Modifying Surface

When glass is immersed in a sodium hydroxide solution, the bond of silicon-oxygen on the surface is cleaved to produce a hydroxyl residue, so that the wettability of the glass is improved. An acrylic plate shows improved wettability when it is immersed in a basic solution similarly to the glass, based on the principles that an ester group on the surface is hydrolyzed to expose a hydroxyl residue or a carboxyl residue to improve the hydrophilicity.

### (b) Coating Method

The coating is performed through spin coating, dip coating, bar coating, coating with an applicator, spray coating, flow coating or the like. However, the present invention is not limited particularly to specific methods. To provide control for an appropriate thickness, it is necessary to optimize the concentration of the coating and the conditions in the individual coating methods. For the spin coating, the membrane thickness depends on the rotation rate and rotation time. Especially, the rotation rate has a great influence and the membrane tends to be thinner as the rotation rate is higher. For the dip coating, the membrane thickness depends on the immersion time and the lifting speed. Especially, the lifting speed has a great influence and the membrane tends to be thinner as the lifting speed is lower. The individual conditions require an appropriate number for the bar coating, the size of a gap for the coating with an applicator, the traveling speed of a spray for the spray coating, and the angle of the held base material and the used amount of the coating for the flow coating.

The target membrane thickness in the coating is desirably 50 to 170 nm when the reflecting membrane or the enhanced reflecting membrane is formed. Theoretically, the reflective index is at the maximum when t=λ/4n, where t represents the membrane thickness, λ represents the wavelength of incident light, and n represents the refractive index of a medium on which light is incident (refractive index of the high-refractive-index membrane according to the present invention).

When the wavelength of the incident light falls in the visible region (380 to 760 nm), or corresponds to a wavelength of a semiconductor laser (405 nm, 670 nm, 780 nm, 830 nm or the like) or to a wavelength of a YAG laser (1064 nm or the like), and the reflective index of the high-refractive-index membrane is 1.6 to 2.0, a desirable minimum thickness is 48 nm (380/(4×2.0)≈48). A thickness less than 48 nm does not function sufficiently as the high-refractive-index membrane when light in the visible light region is incident thereto. In view of the distribution of thickness in forming the membranes, the minimum thickness is desirably aimed at 50 nm which is slightly larger than 48 nm mentioned above. On the other hand, the maximum thickness is desirably 166 nm (1064/(4×1.6)≈166). In view of the distribution of thickness in forming the membranes, the maximum thickness is desirably aimed at 170 nm which is slightly larger than 166 nm. From those conditions, it is appropriate for the thickness of the high-refractive-index membrane according to the present invention to select range from 50 to 170 nm for use in the reflecting membrane or the enhanced reflecting membrane.

In forming the anti-reflecting membrane, the reflective index is at the minimum when the thickness t is equal to λ/2n or λ/4n. However, this depends on the final layer structure. In a similar manner to the reflecting membrane and the enhanced reflecting membrane, a desirable minimum thickness is 48 nm (380/(4×2.0)≈48) and a desirable maximum thickness is 333 nm (1064/(2×1.6)≈333). In view of the distribution of thickness in forming the membranes, the thicknesses are desirably aimed at 50 nm and 340 nm which are slightly larger than the abovementioned calculation results. From those conditions, it is appropriate for the thickness of the high-refractive-index membrane according to the present invention to select range from 50 to 340 nm for use in the anti-reflecting membrane.

### (c) Heating

After the coating step, heating is performed in order to vaporize the solvent or change a dealcohol reaction of titaniasol into titanium oxide.

The heating temperature should be lower than the temperature to which the base material is resistant. It is necessary to select the solvent, the base material, and heating equipment therefor. In addition, since a difference in volume contraction rate between the membrane and the base material in cooling after the heating may cause problems such as peeling of the membrane and deformation of the base material, it is desirable to select the base material and the membrane of which the coefficients of linear thermal expansion are close.

### (2) Coating Material for Low-Refractive-Index Membrane

The low-refractive-index membrane can be formed by vapor deposition of a low-refractive-index material such as magnesium fluoride, or coating and heating of a fluoric resin, for example Cytop (manufactured by ASAHI GLASS). However, a vacuum process such as the vapor deposition requires a large amount of energy and a vacuum chamber accommodating the shape and size of the base material. On the other hand, a transparent fluoric resin such as Cytop is dissolved or swelled in a fluoric solvent, so that the low-refractive-index membrane formed of such a fluoric resin may be dissolved or swelled in soil-resistant treatment with a fluoric material after the formation of the reflecting membrane. To address this, the present invention employs a coating material made of a silicon oxide material to provide a membrane which is formed without using a vacuum process such as vapor deposition and is not dissolved or swelled in a fluoric solvent. Specifically, the composition of the coating includes particles of silicon oxide, a hydrolytic silicon compound, and a solvent.

The hydrolytic silicon compound is changed into silicon oxide through a dealcohol reaction, a dehydration reaction and the like by heating, and this silicon oxide serves as a binder in the membrane. The silicon oxide particles serve to form voids in the membrane. When the particles are stacked in the membrane, voids are produced between the particles. Some of the voids are filled in with the binder of silicon oxide and the remainder is left as voids in the membrane. While silicon oxide has a refractive index of approximately 1.5, the voids have a refractive index of 1.0. The resultant membrane has a refractive index lower than 1.5. A transparent material for use in the base material of the optical material such as glass, acrylic resin, polycarbonate resin, and PET resin has a refractive index of approximately 1.5, so that the membrane of silicon oxide including the voids has a refractive index lower than that of the base material of the optical material. The voids can be seen from the TEM photograph of the section (see 19 in FIG. 5).

The refractive index of the low-refractive-index membrane formed in the abovementioned manner is approximately 1.1 to 1.4. The refractive index can be controlled by the size, shape, and percentage of the particles contained in the membrane. The refractive index also depends on the type of the solvent, the heating temperature in forming the membrane and the like since the solvent in the coating material is changed from liquid into gaseous form and the volume thereof is increased to produce voids in volatilization of the solvent.

In addition, when a hydrolytic silicon compounds is heated to cause a dealcohol reaction, a dehydration reaction and the like, it contracts to produce some voids to result in a refractive index lower than 1.5. The phenomenon depends on the chemical structure of the hydrolytic silicon compound, and therefore the degree of the production of the voids varies. In the circumstances, the reduction of the refractive index varies, but the refractive index can be reduced to approximately 1.4 or 1.45 even when the particles are not used. The silicon oxide particles, the hydrolytic silicon compound, the solvent will hereinafter be described.

### (i) Silicon Oxide Particles

For spherical particles of silicon oxide, the average particle diameter is desirably 190 nm or less to prevent scattering of visible light (at wavelengths of 380 to 760 nm) incident on the membrane. When a diameter is larger than this value, the membrane looks cloudy by scattering of incident light, and therefore there may occur disadvantages in use for displays and the like. For chain-shaped particles of silicon oxide, the chain desirably has a thickness of 190 nm or less for the same reason as the abovementioned one. As the diameter of the silicon oxide particles is smaller, the transparency is higher. Thus, the average particle diameter is preferably 100 nm or less. The lower limit of the size of the silicon oxide particles in the present invention is approximately 9 nm in view of available particles, but a smaller size causes no problem if the particles are favorably diffused in the membrane.

Exemplary silicon oxide particles include aerosil manufactured by NIPPON AEROSIL CO., LTD. It is necessary to select particles having an average diameter of approximately several nm to 100 nm among them. Another example of the silicon oxide particles is colloidal silica, for example organosilicasol and Snowtex manufactured by NISSAN CHEMICAL INDUSTRIES. These particles are highly hydrophilic since they have a number of hydroxyl residues on the surface. In addition, since they are dispersed in an organic solvent or water, they are easily dispersed in the coating. A membrane formed of the particles as members is hydrophilic and has an extremely low resistance, specifically, approximately 1×10¹⁰ to 10×10¹⁰Ω. This value is very small compared with glass, acrylic resin, polycarbonate resin, PET resin and the like and only from one-ten-thousandth to one-millionth thereof, so that dirt including dust hardly attaches thereto. As a result, an optical material having the membrane according to the present invention on the outermost surface has an advantage that no dust attaches to the surface thereof for a long time period even in a dry room.

Chain-shaped particles of silicon oxide are preferable among various types of colloidal silica. The chain-shaped particles tend to reduce the refractive index of the resulting membrane as compared with spherical particles if the particles of the same percentage are contained in the membranes. The binder of the membrane, a so-called supporter, is realized by silicasol, and silicon oxide has an extremely limited function as the supporter of the membrane. If silicasol is not contained, the shape of the membrane is hardly maintained, and thus simply takes the form of powder. To enhance the physical strength, the membrane preferably contains a low percentage of silicon oxide. While the reason why the chain-shaped silicon oxide can provide a membrane having a lower refractive index than the spherical silicon oxide is not obvious, it is expected that the chain-shaped silicon oxide takes the form which easily produces more voids than the spherical silicon oxide in the membrane. An example of the chain-shaped silicon oxide particles is organosilicasol IPA-ST-UP manufactured by NISSAN CHEMICAL INDUSTRIES.

### (ii) Hydrolytic Silicon Compound

A highly transparent inorganic polymer material is preferable as the coating material. Inorganic polymer materials include a silicon compound having a hydrolysable residue (with a general name of silicasol) and a titanium compound having a hydrolysable residue (with a general name of titaniasol). These are compounds made by polymerization of alkoxysilane or alkoxytitanium to a molecular weight of approximately several thousands and generally are soluble in an organic solvent. They can be heated to form a binder of silicon oxide or titanium oxide. Among them, the material that has a lower refractive index is advantageously selected in forming the reflecting membrane and the anti-reflecting membranes. Thus, in the present invention the silicon compound having a hydrolysable residue is preferable for the material of low-refractive-index membrane.

Silicon compounds having a hydrolysable residue include silicasol and alkoxysilane having various substituents such as an amino group, a chloro group, and a mercapto group. Specific materials are shown in the following description of silicon compounds having a hydrolysable residue. Silicasol is one of silicon compounds having a hydrolysable residue. This is a substance which changes into silicon oxide through heating. Since the resulting silicon oxide is highly transparent to provide high light transmittance, it is preferable for use in a greenhouse, an aquarium, an image forming apparatus and the like. Silicasol can diffuse the particles of silicon oxide in the membrane more than acrylic resin and polycarbonate resin. If the particles of silicon oxide cannot be diffused in the membrane, that is, the particles flocculates, the membrane disadvantageously becomes cloudy to scatter incident light to reduce the light transmittance. Silicasol is typically prepared in the following manner. Tetraalkoxysilane is heated under the weakly-acidic conditions, and then an alkoxy group is hydrolyzed into a hydroxyl residue which reacts with a nearby alkoxysilane residue and forms a bond of silicon-oxide-silicon to cause the polymerization. The average molecular weight is typically several thousands. A higher average molecular weight (a molecular weight of several hundreds) causes a problem that when a membrane of silicon oxide is formed in later heat, one part of the membrane is volatized. A higher average molecular weight (a molecular weight of several tends of thousands) causes a problem of precipitation in the formation of a coating since that silicasol is insoluble in the solvent.

Tetraalkoxysilane used in the formation of silicasol includes tetramethoxysilane, tetraethoxysilane, tetrapropoxysilane, tetraisopropoxysilane, tetraisobutoxysilane, and tetrabutoxysilane. Besides, a silicon compound having a chlorine group instead of an alkoxysilane residue can be used, for example silicon tetrachloride.

Tetraalkoxysilane containing a bonded alkoxy group having a large molecular weight is effective to provide the membrane having the lowest possible refractive index since the volume largely contracts due to a dealcohol reaction.

Silicon compounds having a hydrolysable residue other than silicasol include compounds having an amino residue, a chloro residue, a mercapto residue or the like other than tetraalkoxysilane. Specific examples include 3-aminopropyltriethoxysilane, 3-aminopropyltrimethoxysilane, N-(2-aminoethyl)-3-aminopropyltrimethoxysilane, 3-chloropropyltrimethoxysilane, 3-chloropropylmethyldimethoxysilane, 3-mercaptopropyltrimethoxysilane, vinyltrimethoxysilane, vinyltriethoxysilane, 3-glycidoxypropyltirmethoxysilane, 3-grycidoxypropylmethyldimethoxysilane, and 3-methacryloxypropyltrimethoxysilane.

(iii) Additive Agent

If the silicon oxide particles are not sufficiently diffused in the silicon compound having a hydrolysable residue serving as a matrix and the solvent, the particles cause the problem that they flocculate to form large secondary particles to make the membrane look cloudy.

Although it is preferable to use a solvent for favorably diffusing the silicon oxide particles, such a solvent may not be used depending on the type of the base material. In this case, a dispersant is added thereto. Specifically, a non-ionic dispersant is preferable. Some of ionic dispersants may promote polymerization of the silicon compound having a hydrolysable residue to significantly increase the viscosity of the coating material before application to the base material. In some cases, the coating may be hardened into gel form or even a solid body which cannot be applied to the base material. It is thus desirable to check if such a phenomenon would occur before use. Since the use of dispersant tends to reduce the strength of the membrane, it is desirable to avoid use of the dispersant as much as possible or to use the smallest possible amount if it is used.

### (iv) Solvent

An alcohol solvent having a hydroxyl residue is preferable for the coating material in that it easily dissolves the silicon compound having a hydrolysable residue and easily disperses the silicon oxide particles. Specific examples include ethanol, n-propanol, isopropanol, n-butanol, isobutanol, tert-butanol, n-pentanol, iso pentanol, and tert-pentanol. Other solvents having a plurality of hydroxyl residues such as ethyleneglycol, propyleneglycol, diethyleneglycol, triethyleneglycol, and glycerin are also preferable for the same reasons. A solvent having a plurality of hydroxyl residues has a higher boiling point than a solvent having a single hydroxyl residue if they have similar molecular weights, so that the former solvent is effectively selected when a less volatile solvent needs to be used in terms of the coating method and conditions.

An alcohol solvent or a solvent having a plurality of hydroxyl residues is also preferable since it hardly swells, deforms, or dissolves the base material formed of polycarbonate resin and acrylic resin. An alcohol solvent containing a higher number of carbon atoms tends to have a higher boiling point. As the number of branches is increased, the boiling point tends to be reduced. The solvent having a boiling point slightly lower than the temperature of heat curing in the membrane formation described later readily provides a membrane having a lower refractive index. This is because the solvent is vaporized to produce voids in the membrane and the voids occupy a large volume of the membrane.

### (v) Membrane Forming Method

The outlines of the method for forming the membrane according to the present invention will hereinafter be described. First, the abovementioned coating material is applied to the base material, and heating is immediately performed to quickly vaporize the solvent in the coating to produce bubbles in the membrane. The membrane is hardened in this state to hold the bubbles as voids, thereby providing the low-refractive-index membrane for use in the present invention.

FIG. 5 shows the photograph of the section of the reflecting membrane according to the present invention. The base material is formed of glass. The low-refractive-index membrane is formed on the glass, and the high-refractive-index membrane is formed thereon. Some voids (corresponding to white portions 19 in the photograph) are seen inside the low-refractive-index membrane in the present invention.

The sizes of the voids are from approximately 5 to 100 nm when observed along the longer axes since they have irregular shapes. To confirm the voids, the presence strengths of the elements contained in the voids and the remaining portions except for the voids were measured. FIG. 7 shows graphs representing the presence strengths of the elements in the low-refractive-index membrane as a result of the measurement. FIG. 7(a) shows the voids and FIG. 7(b) shows the portions except for the voids. It can be seen from FIG. 7 that the voids have smaller presence strengths of carbon, oxygen, silicon and the like than the portions except for the voids. This confirms the presence of the voids.

As described above, the refractive index can be controlled by changing the percentages of silicon oxide (having a refractive index of approximately 1.5) serving as the binder of the membrane and the voids (having a refractive index of approximately 1.0) in the membrane. Specifically, the refractive index is lower as the percentage of the voids is larger.

Since the vaporization of the solvent in the coating during the heat curing contributes to the formation of the voids, the formation of the voids can also be controlled by the boiling point of the solvent used in the membrane formation and by the temperature of the heat curing after the application of the coating material to the base material.

The steps for forming the membrane will be described below. If the base material has low wettability, the coating material cannot be uniformly applied in the membrane formation, and thus pretreatment should be performed. Next, the coating is performed on the base material, and subsequently, the heating is performed to form the membrane.

### (a) Pretreatment

In the pretreatment, the base material is washed and the wettability of the base material is improved in order to uniformly dispose the coating.

### 1. Washing of Base Material

The washing of the base material is performed by using a solvent, a washing agent or the like which can satisfactorily dissolve or remove dirt attached to the base material. However, when the base material is made of resin, for example acryl or polycarbonate, an alcohol solvent such as methanol, ethanol, propanol, and butanol is more desirable than a solvent which dissolves the surface to produce cloudiness (such as tetrahydrofuran and dioxane). When the base material is made of glass, the base material may be immersed in a basic solution (for example, a sodium hydroxide solution) to slightly etch the surface to remove dirt together, and preferably, heating may also be performed during the immersion to attain quick proceeding of the etching. However, the heating for a long time may cause the progression of the etching more than necessary, thereby clouding the surface. Therefore, the etching should be performed carefully.

### 2. Improvement in Wettability of Base Material

Since the improved wettability of the base material helps uniform application of the coating thereto to reduce variations in the membrane thickness, excellent optical characteristics can be provided. Methods for improving the wettability of the base material include a method of modifying a surface with an apparatus such as a plasma irradiation apparatus and a method of chemically modifying a surface with an acid, a basic solution or the like.

Method of Modifying Surface with Apparatus

The method includes oxygen plasma irradiation, placement in an ozone atmosphere, and UV irradiation. In any of them, active oxygen acts on the surface of the base material to produce a hydroxyl residue, a carboxyl residue or the like. Since these residues are hydrophilic, the surface on which these residues are produced has improved wettability to make it easy to provide a membrane having a uniform thickness with the coating. In the UV irradiation, the UV changes oxygen in the air into an active state to modify the surface, so that it can provide the effects similar to those of the oxygen plasma irradiation and the placement in an ozone atmosphere. The method also includes argon plasma. The wettability is also improved by the irradiation of argon plasma. In the case where the output from a high-frequency power of a plasma generating apparatus is the same, the irradiation period of argon plasma should be longer than that of oxygen plasma.

Method of Chemically Modifying Surface

When glass is immersed in a sodium hydroxide solution, the bond of silicon-oxygen on the surface is cleaved to produce a hydroxyl residue, so that the wettability of the glass is improved. An acrylic plate also shows improved wettability when it is immersed in a basic solution similarly to the glass on the principles that an ester group on the surface is hydrolyzed to expose a hydroxyl residue or a carboxyl residue to improve the hydrophilicity.

### (b) Coating Method

The coating is performed through spin coating, dip coating, bar coating, coating with an applicator; spray coating, flow coating or the like and the present invention is not limited particularly to specific methods. To provide control for an appropriate thickness, it is necessary to optimize the concentration of the coating material and the conditions in the individual coating methods. For the spin coating, the membrane thickness depends on the rotation rate and rotation time. Especially the rotation rate has a great influence and the membrane tends to be thinner as the rotation rate is higher. For the dip coating, the membrane thickness depends on the immersion time and the lifting speed. Especially the lifting speed has a great influence and the membrane tends to be thinner as the lifting speed is lower. The individual conditions include an appropriate number for the bar coating, the size of a gap for the coating with an applicator, the traveling speed of a spray for the spray coating, and the angle of the held base material and the used amount of the coating material for the flow coating.

The target membrane thickness in the coating is desirably 60 to 180 nm. Theoretically, the reflective index is at the maximum when t=λ/4n, where t represents the membrane thickness, λ represents the wavelength of incident light, and n represents the refractive index of a medium on which light is incident (refractive index of the transparent base material and the high-refractive-index membrane for use in the present invention). When the low-refractive-index membrane is combined with the high-refractive-index membrane, the maximum reflective index is given at this membrane thickness.

In the case where the wavelength of the incident light falls in the visible region (380 to 760 nm), a wavelength of a semiconductor laser (405 nm, 670 nm, 780 nm, 830 nm or the like), or a wavelength of a YAG laser (1064 nm or the like), and further the medium is formed of a material such as glass (having a refractive index of approximately 1.5) and a sapphire glass base material of a relatively high refractive index (having a refractive index of approximately 1.7) in view of the refractive index, the desirable minimum thickness is 56 nm (380/(4×1.7)=56). The thickness less than 56 nm does not provide the required reflective index when light in the visible light region is incident thereon. In view of the distribution of thickness in forming the membranes, the minimum thickness is desirably aimed at 60 nm which is slightly larger than 56 nm mentioned above. On the other hand, the maximum thickness is desirably 177 nm (1064/(4×1.5)=177). In view of the distribution of thickness in forming the membranes, the maximum thickness is desirably 180 nm. From those conditions, it is appropriate for the thickness of the low-refractive-index membrane according to the present invention to select the range of from 60 to 180 nm.

### (c) Heating

After the coating step, heating is performed in order to vaporize the solvent or help the progress of polymerization for some binders. The heating temperature is set equal to or higher than the boiling point of the solvent to produce bubbles in the membrane that finally remain as voids in the membrane, resulting in a reduced refractive index of the membrane.

The heating temperature should be lower than the temperature to which the base material is resistant, in addition to the consideration of the boiling point of the solvent. When a thermosetting material is used for the binder, the heating temperature needs to be set equal to or higher than the thermosetting temperature. Thus, it is necessary to select the solvent, the base material, and the binder material. In addition, since there is a difference in volume contraction rate between the membrane and the base material in cooling after the heating may cause problems such as peeling of the membrane and deformation of the base material, it is desirable to select the base material and the membrane which are made of similar materials or of which coefficients of thermal expansion are close. From this viewpoint, when silicasol preferable for the binder and silicon oxide particles preferable for the inorganic oxide particles are used, the resultant membrane from the heating is formed of silicon oxide. In this case, glass or quartz of which coefficient of thermal expansion is close to that of silicon oxide is preferable for the base material.

### (3) Soil-Resistant Treatment

The reflecting membrane, enhanced reflecting membrane, and anti-reflecting membrane according to the present invention are obtained after the heat curing. The soil resistance of those surfaces can be improved by forming a layer made of a liquid-repellent fluorine-containing compound thereon. However, the layer made of a liquid-repellent fluorine-containing compound needs to have an extremely small thickness to prevent reduction in the optical performance of the formed reflecting membrane, enhanced reflecting membrane, and anti-reflecting membrane. Specifically, the reflective index is not affected if the thickness is less than 48 nm which is the lower limit of the thickness described in the methods for forming the high-refractive-index membrane and the low-refractive-index membrane.

### (i) Outlines of Treatment

The formation of the layer made of the liquid-repellent fluorine-containing compound includes the following two types.

Film Made of Liquid-Repellent Fluorine-Containing Compound

This is a method for forming a film made of a liquid-repellent fluorine-containing compound. The surface is covered with the film to exert liquid repellency. If the anti-reflecting membrane has a low resistance, the covering liquid-repellent fluorine-containing compound increases the surface resistance to result in a tendency to attract dirt including dust.

Exemplary materials for forming the film include Cytop (manufactured by ASAHI GLASS) and INT304VC (manufactured by INT screen Co., Ltd.). These are diluted in a solvent and applied and then heated to vaporize the solvent, and in some cases heat curing is performed, to form the film.

Monomolecular Film Made of Compound Including Perfluoropolyether Chain or Perfluoroalkyl Chain

This is a method for binding a compound including a perfluoropolyether chain, a perfluoroalkyl chain, or a fluoroalkyl chain and including an alkoxysilane residue to the surface of the reflecting membrane, enhance reflecting membrane, of anti-reflecting membrane. The alkoxysilane residue in the compound chemically binds to the silicon oxide part or the titanium oxide part on the surface of the reflecting membrane, enhanced reflecting membrane, or anti-reflecting membrane through a dealcohol reaction to form a monomolecular film. Specifically, those compounds having the following structures are used:

[F{CF(CF₃)—CF₂O}ₙ—CF(CF₃)]—X—Si(OR)₃

{F(CF₂CF₂CF₂O)}ₙ—X—Si(OR)₃

(RO)₃Si—X—{(CF₂CF₂O)ₘ(CF₂O)}ₙ—X—Si(OR)₃

{H(CF₂)ₙ}—Y—Si(OR)₃

{F(CF₂)ₙ}—Y—Si(OR)₃

where X represents a bond part between the perfluoropolyether chain and the alkoxysilane residue, Y represents a bond part between the perfluoroalkyl chain or the fluoroalkyl chain and the alkoxysilane residue, R represents the alkyl residue, and m and n represent the number of repetition. These compounds do not fully cover the surface of the anti-reflecting membrane. The perfluoropolyether chain, the perfluoroalkyl chain, or the fluoroalkyl chain are present on the anti-reflecting membrane as if the grass grows thereon. Since the surface of the anti-reflecting membrane is not fully covered, the membrane having as low a resistance as 10¹¹Ω can maintain this low resistance after this method is applied.

In addition, the formation of perfluoropolyether chain, the perfluoroalkyl chain, or the fluoroalkyl chain formed on the surface improves the lubrication on the surface. This can reduce physical damage to the surface from rubbing, thereby providing the surface resistant to rubbing.

Thus, the use of a perfluoropolyether compound, a perfluoroalkyl compound, or a fluoroalkyl compound having an alkoxysilane residue at the end is effective in forming the liquid-repellent layer since it can maintain the low resistance on the surface and improve the resistance to rubbing in addition to the soil resistance.

### (ii) Liquid-Repellent Agent for Use in Soil-Resistant Treatment

As described above, the perfluoropolyether compound, the perfluoroalkyl compound, or the fluoroalkyl compound having an alkoxysilane residue at the end is effective as the liquid-repellent agent. Exemplary liquid-repellent agents and methods for forming the liquid-repellent film are shown in the following.

Liquid-Repellent Agent

Specific examples of the perfluoropolyether compound or the perfluoroalkyl compound having an alkoxysilane residue at the end include the following compounds 1 to 16:

Compound 1: F{CF(CF₃)—CF₂O}ₙ—CF(CF₃)—CONH— (CH₂)₃—Si(OCH₂CH₃)₃
Compound 2: F{CF(CF₃)—CF₂O}ₙ—CF(CF₃)—CONH— (CH₂)₃—Si(OCH₃)₃
Compound 3: F{CF₂CF₂CF₂O}ₙ—CF₂CF₂—CONH—(CH₂)₃—Si(OCH₂CH₃)₃
Compound 4: F{CF₂CF₂CF₂O}ₙ—CF₂CF₂—CONH—(CH₂)₃—Si(OCH₃)₃

### Compound 5: H(CH₂)₆—CONH—(CH₂)₃—Si(OCH₂CH₃)₃

### Compound 6: H(CH₂)₆—CONH—(CH₂)₃—Si(OCH₃)₃

### Compound 7: H(CH₂)₈—CONH—(CH₂)₃—Si(OCH₂CH₃)₃

### Compound 8: H(CH₂)₈—CONH—(CH₂)₃—Si (OCH₃)₃

Compound 9: F{CF₂CF₂CF₂O}ₙ—CF₂CF₂—CH₂OCONH—(CH₂)₃—Si(OCH₂CH₃)₃
Compound 10: {(H₃CH₂CO)₃Si—(CH₂)₃—NHCO₂H₂CF₂C}{(CF₂CF₂O)ₘ(CF₂O)ₙ}{(H₃CH₂CO)₃Si—(CH₂)₃—NHCO₂H₂CF₂C}

### Compound 11: H(CH₂)₆—CH₂OCONH—(CH₂)₃—Si(OCH₂CH₃)₃

### Compound 12: H(CF₂)₈—CH₂OCONH—(CH₂)₃—Si(OSH₂CH₃)₃

### Compound 13: F(CF₂)₆—(CH₂)₂—Si(OCH₃)₃

### Compound 14: F(CF₂)₈—(CH₂)₂—Si(OCH₃)₃

### Compound 15: F(CF₂)₆—(CH₂)₂—Si(OCH₂CH₃)₃

### Compound 16: F(CF₂)₈—(CH₂)₂—Si (OCH₂CH₃)₃

Compounds 1 to 12 are obtained by performing the following synthesis method. Compounds 13 to 16 are available from HYDRUS CHEMICAL as compound names of 1H,1H,2H,2H-perfluorooctyltrimethoxysilane, 1H,1H,2H,2H-pefluorooctyltriethoxysilane, 1H,1H,2H,2H-perfluorodecyltrimethoxysilane, and 1H,1H,2H,2H-perfluorodecyltriethoxysilane. Other materials which are commercially available include OPTOOL DSC manufactured by DAIKIN INDUSTRIES. Compounds 1 to 4, 9, and 10 include fluorine chain of perfluoropolyether. A liquid-repellent film made from the compound having the fluorine chain is characterized in that the water repellency hardly reduces (with a reduction of 5° or less) even after it is immersed in engine oil or gasoline for a long time period (1000 hours) other than water. These compounds are expressed as the following formulas:

[F{CF(CF₃)—CF₂O}ₙ—CF(CF₃)]—X—Si(OR)₃

{F(CF₂CF₂CF₂O)ₙ}—X—Si(OR)₃

(RO)₃Si—X—{(CF₂CF₂O)ₘ(CF₂O)ₙ}—X—Si(OR)₃

where X represents a bond part between the perfluoropolyether chain and the alkoxysilane residue, R the alkyl residue, and m and n represent the number of repetition.

If Compounds 5 to 8 and Compounds 12 to 16 are immersed in engine oil or gasoline for a long time period (1000 hours), the angle of contact with water is reduced from approximately 110° before the immersion to substantially the same level as the angle of contact of the base material.

### (Synthesis of Compound 1)

Krytox 157 FS-L (average molecular weight of 2500) (25 parts by weight) manufactured by DuPont was dissolved into PF-5080 (100 parts by weight) manufactured by 3M Company, thionyl chloride (20 parts by weight) was added thereto, and it was refluxed for 48 hours while being stirred. Thionyl chloride and PF-5080 were vaporized by an evaporator to provide acid chloride of Krytox 157 FS-L (25 parts by weight). PF-5080 (100 parts by weight), Sila-Ace S330 (3 parts by weight) manufactured by CHISSO Corporation, and triethylamine (3 parts by weight) were added thereto and stirred at room temperature for 20 hours. The resulting reaction solution was filtered through RADIOLITE FINEFLOW A manufactured by SHOWA CHEMICAL INDUSTRY, and PF-5080 in the filtrate was vaporized by the evaporator to provide Compound 1 (20 parts by weight).

### (Synthesis of Compound 2)

Compound 2 (20 parts by weight) was obtained in the same manner as the synthesis of Compound 1 except that Sila-Ace S360 (3 weight parts) manufactured by CHISSO Corporation was used instead of Sila-Ace S330 (3 parts by weight) manufactured by CHISSO.

### (Synthesis of Compound 3)

Compound 3 (30 parts by weight) was obtained in the same manner as the synthesis of Compound 1 except that DEMNUM SH (average molecular weight of 3500) (35 parts by weight) manufactured by DAIKIN INDUSTRIES was used instead of Krytox 157 FS-L (average molecular weight of 2500) (25 parts by weight) manufactured by DuPont.

### (Synthesis of Compound 4)

Compound 4 (30 parts by weight) was obtained in the same manner as the synthesis of Compound 1 except that Sila-Ace S360 manufactured by CHISSO Corporation was used instead of Sila-Ace S330 (3 parts by weight) manufactured by CHISSO Corporation and DEMNUM SH (average molecular weight of 3500) (35 parts by weight) manufactured by DAIKIN INDUSTRIES was used instead of Krytox 157 FS-L (average molecular weight of 2500) (25 parts by weight) manufactured by DuPont.

### (Synthesis of Compound 5)

Compound 5 (3.5 parts by weight) was obtained in the same manner as the synthesis of Compound 1 except that 7H-dodecafluoroheptanoic acid (molecular weight of 346.06) (3.5 parts by weight) manufactured by DAIKIN INDUSTRIES was used instead of Krytox 157 FS-L (average molecular weight of 2500) (25 parts by weight) manufactured by DuPont.

### (Synthesis of Compound 6)

Compound 6 (3.5 parts by weight) was obtained in the same manner as the synthesis of Compound 1 except that 7H-dodecafluoroheptanoic acid (molecular weight of 346.06) (3.5 parts by weight) manufactured by DAIKIN INDUSTRIES was used instead of Krytox 157 FS-L (average molecular weight of 2500) (25 parts by weight) manufactured by DuPont and Sila-Ace S320 (2 parts by weight) manufactured by CHISSO Corporation was used instead of Sila-Ace S330 (2 parts by weight) manufactured by CHISSO Corporation.

### (Synthesis of Compound 7)

Compound 7 (4.5 parts by weight) was obtained in the same manner as the synthesis of Compound 1 except that 9H-hexadecafluoronanoic acid (molecular weight of 446.07) (4.5 parts by weight) manufactured by DAIKIN INDUSTRIES was used instead of Krytox 157 FS-L (average molecular weight of 2500) (25 parts by weight) manufactured by DuPont.

### (Synthesis of Compound 8)

Compound 8 (4.5 parts by weight) was obtained in the same manner as the synthesis of Compound 1 except that 9H-hexadecafluoronanoic acid (molecular weight of 446.07) (4.5 parts by weight) manufactured by DAIKIN INDUSTRIES was used instead of Krytox 157 FS-L (average molecular weight of 200) (25 parts by weight) manufactured by DuPont and Sila-Ace S320 (2 parts by weight) manufactured by CHISSO was used instead of Sila-Ace S310 (2 parts by weight) manufactured by CHISSO Corporation.

### (Synthesis of Compound 9)

DEMNUM SA (average molecular weight of 4000) (40 parts by weight) manufactured by DAIKIN INDUSTRIES was dissolved in HFE-7200 (100 parts by weight) manufactured by 3M Company, and di-n-butyltindilaurate (0.3 parts by weight) was added thereto, followed by cooling to a temperature of −5 to 0° C. while dry nitrogen was flowed. 3-isocyanatepropyltriethoxysilane (3 parts by weight) was dropped and the solution was stirred for 12 hours. During the stirring, nitrogen was flowed and the cooling was continued. HFE-7200 was vaporized by an evaporator, followed by extraction with PF-5060 manufactured by 3M Company, and the extracted solution was cleaned several times by dichloromethane. PF-5060 was vaporized to obtain Compound 9 (35 parts by weight).

### (Synthesis of Compound 10)

Compound 10 (30 parts by weight) was obtained in the same manner as the synthesis of Compound 9 except that FOMBRIN Z-DOL (average molecular weight of 4000) (20 parts by weight) manufactured by AUSIMONT was used instead of DEMNUM SA (average molecular weight of 4000) (40 parts by weight) manufactured by DAIKIN INDUSTRIES.

### (Synthesis of Compound 11)

Compound 11 (2 parts by weight) was obtained in the same manner as the synthesis of Compound 9 except that 7H-dodecafluoroheptanoic acid (molecular weight of 346.06) (3.5 parts by weight) manufactured by DAIKIN INDUSTRIES was used instead of DEMNUM SA (average molecular weight of 4000) (40 parts by weight) manufactured by DAIKIN INDUSTRIES.

### (Synthesis of Compound 12)

Compound 12 (4 parts by weight) was obtained in the same manner as the synthesis of Compound 9 except that 9H-hexadecafluoronanoic acid (molecular weight of 446.07) (4.5 parts by weight) manufactured by DAIKIN INDUSTRIES was used instead of DEMNUM SA (average molecular weight of 4000) (40 parts by weight) manufactured by DAIKIN INDUSTRIES.

Method for Forming Liquid-Repellent Film

The liquid-repellent film with the perfluoropolyether compound, the perfluoroalkyl compound, or the fluoroalkyl compound having an alkoxysilane residue at the end is formed in the following manner.

First, the perfluoropolyether compound, the perfluoroalkyl compound, or the fluoroalkyl compound having an alkoxysilane residue at the end is dissolved in a solvent at a concentration of approximately 0.01 to 1.0 wt %, depending on the coating method. Since the alkoxysilane residue is gradually hydrolyzed with moisture in the solvent or moisture entering the solvent from the air, it is desirable to dewater the solvent or to select a solvent which hardly dissolves water such as a fluoric solvent. Specific examples of the fluoric solvent include FC-72, FC-77, PF-5060, PF-5080, HFE-7100, HFE-7200 manufactured by 3M Company, and VERTRIL XF manufactured by DuPont. In this manner, the solution is prepared (hereinafter referred to as the liquid-repellent treatment agent) in which the perfluoropolyether compound or the perfluoroalkyl compound is dissolved.

Next, the liquid-repellent treatment agent is applied to the surface of the anti-reflecting membrane. The application is performed with a general coating method such as dip coating and spin coating. Next, heating is performed. The heating is a process necessary for the alkoxysilane residue to bind to the hydroxyl residue or the like which is present on the surface and is typically performed at 120° C. for approximately 10 minutes, at 100° C. for approximately 30 minutes, or at 90° C. for approximately one hour. Room temperature can be used but require a considerable time period for the treatment.

Finally, the surface is rinsed with a fluoric solvent to remove the excess liquid-repellent agent, thereby completing the liquid-repellent treatment. The solvent mentioned in the description of the liquid-repellent treatment agent can be used as the solvent in the rinse.

### (4) Applications

As described above, the present invention relates to the optical material, the image forming apparatus or the like having the reflecting membrane, enhanced reflecting membrane, or anti-reflecting membrane. In the following, description will be firstly made for the optical material and then products such as the image forming apparatus to which the optical material is applicable.

In Examples below, the method for forming the reflecting membrane and the anti-reflecting membrane according to the present invention will be described. While the base material, the solvent and the like vary among the products, the membrane materials and the like are common and thus only the membrane formation method will be described in Examples. The place where the reflecting membrane and the anti-reflecting membrane according to the present invention are formed in the products will be described in this section.

### (i) Optical Material

In this part, the applications of the optical material will be described according to each function.

### (A) Reflecting Membrane

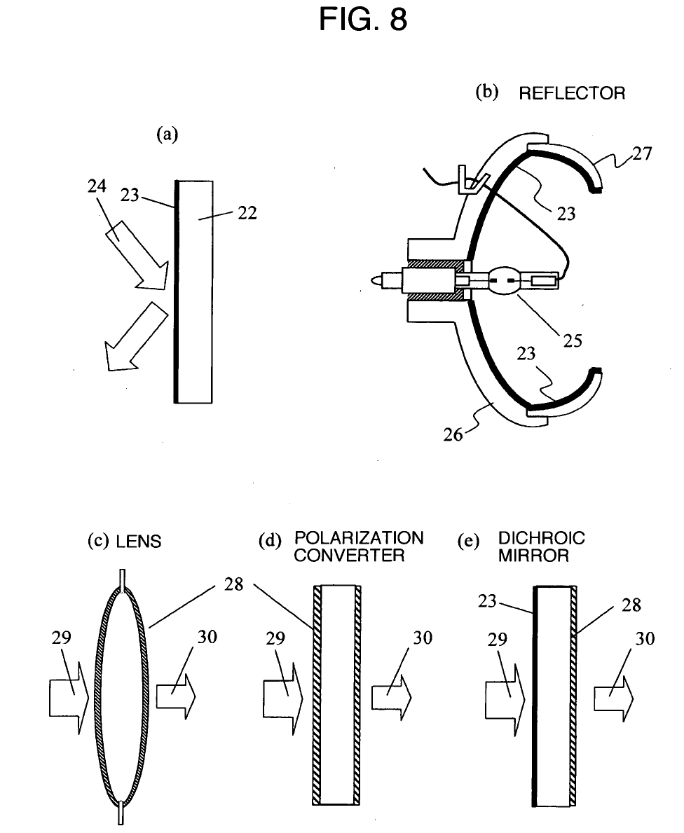

The reflecting membrane according to the present invention can be formed not only on a glass base material but also on a transparent base material such as a polycarbonate resin base material and acrylic resin base material. Applications thereof include a mirror, a reflector, and a dichroic mirror as shown in FIG. 8. For the mirror and reflector, membranes having different thicknesses need to be formed as shown in FIG. 3 in order to provide a wider band in which a high reflective index is given.

The mirror in FIG. 8(a) includes a reflecting membrane 23 according to the present invention on the surface of a base material 22 to allow incident light 24 to be reflected. While the mirror is shown as a flat plate, a curved mirror described later and a tubular mirror are included in the scope of the present invention.

The reflector in FIG. 8(b) includes two separate base material portions, that is, a first reflector 26 holding a light source 25 and a second reflector 27 other than the first reflector 26. In this case, the first reflector 26 needs to have high heat resistance to avoid deformation due to heat emitted from the light source 25. However, the second reflector 27 may be formed of a base material made of resin having low heat resistance since it is not in direct contact with the light source 25. A reflector which is not divided into two parts is included in the scope of the present invention since such a reflector can be realized by the stacked structure of the high-refractive-index membrane and the low-refractive-index membrane according to the present invention.

Each of a lens in FIG. 8(C) and a polarization converter in FIG. 8(d) includes an anti-reflecting membrane 28 according to the present invention, later described, formed on both sides thereof, so that they hardly reflect incident light 29 on the surfaces and can emit exiting light 30.

The dichroic mirror in FIG. 8(e) includes a reflecting membrane according to the present invention formed on the surface on which light is incident and an anti-reflecting membrane according to the present invention on the exit surface such that it reflects light at specific wavelengths and transmits light at the other wavelengths. The anti-reflecting membrane according to the present invention formed on the exit surface prevents interface reflection to increase the amount of exiting light as compared with the case where the anti-reflecting membrane is not formed. Since the dichroic mirror needs to reflect light at specific wavelengths, the membrane is formed to have a suitable thickness.

### (B) Enhanced Reflecting Membrane

The enhanced reflecting membrane according to the present invention can be formed on a transparent base material such as a glass base material, a polycarbonate resin base material, and an acrylic resin base material. The enhanced reflecting membrane is provided for increasing the reflective index of a reflecting membrane made of aluminum, silver or the like. The enhanced reflecting membrane is formed on the reflecting membrane. Applications of the enhanced reflecting membrane include the mirror, the reflector, and the dichroic mirror as shown in FIG. 8. The enhanced reflecting membrane formed on the surface of these reflecting membranes can increase the reflective indexes of the reflecting membranes.

### (C) Anti-Reflecting Membrane

The anti-reflecting membrane according to the present invention can be formed on a transparent base material such as a glass base material, a polycarbonate resin base material, and an acrylic resin base material.

The anti-reflecting membrane is effective for applications in which sunlight is desirably required to be efficiently taken without reflection. For example, the anti-reflecting membrane is applicable to a transparent wall of a greenhouse to promote stable and rapid growth of plants. In addition, the anti-reflecting membrane is applicable to a transparent wall of an aquarium for observation of animals and plants, insects, and fish in order to suppress reflection (superposition) and improve visibility.

Similarly, for the purpose of reducing reflection (superposition) and improving visibility, the present invention contemplates applications of the anti-reflecting membrane to a display apparatus such as a television, a cellular phone, a navigation system, a liquid crystal display, a plasma display, and an organic electroluminescence (EL) display for use in displaying the speed, RPM and the like of a vehicle. Specifically, the anti-reflecting membrane is preferably formed in the outermost surfaces of display parts of those display apparatuses.

In addition, the anti-reflecting membrane can be formed on a surface of a solar battery panel to improve the efficiency of solar energy generation. Since the anti-reflecting membrane can efficiently reflect light such as laser light other than sunlight, it can effectively be used on the outermost surface of an optical recording medium.

In addition to the anti-reflecting effect, the anti-reflecting membrane has a characteristic in which dirt including dust is hardly attached to the outermost membrane due to its low resistance, so that it can achieve the improved light transmittance to enhance visibility even at a low humidity in winter or in an environment with many dust particles. The liquid-repellency given to the anti-reflecting membrane increases the soil resistance, which also improves the light transmittance to increase the visibility.

### (ii) Applicable Products

### (A) Applicable Products in Which Reflecting Membrane and Enhanced Reflecting Membrane are Used

Applicable products in which the reflecting membrane is used include display apparatuses, housing equipment and the like. Description will be made for each of them.

### 1. Display Apparatuses

Projection Type Display Apparatuses

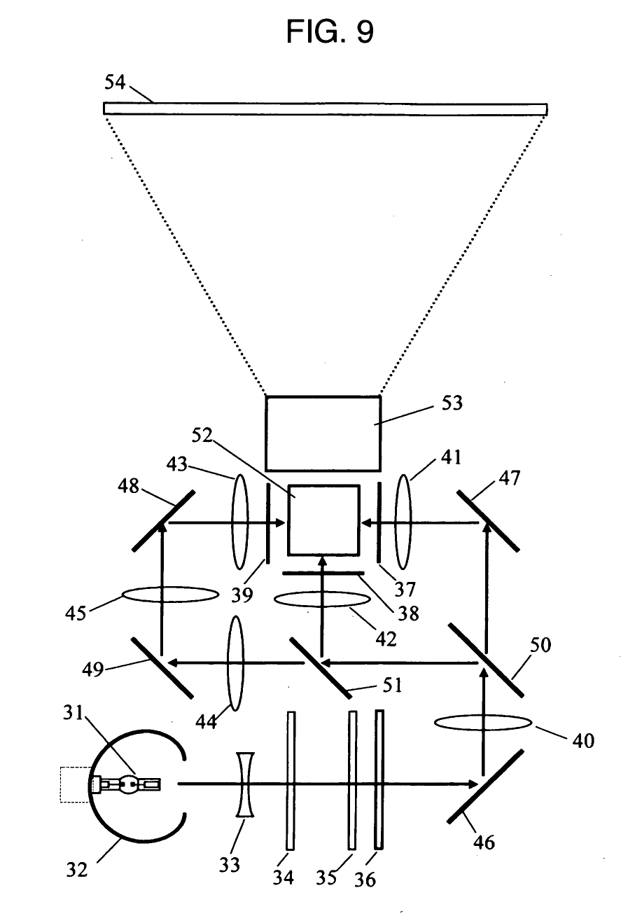

The reflecting membrane, the enhanced reflecting membrane, and the anti-reflecting membrane can be used in a projection type display apparatus among various display apparatuses. The display apparatus includes a plurality of optical materials such as a dichroic mirror, a mirror, and a reflector in an optical system. FIG. 9 is a schematic diagram showing a specific optical system. Description will hereinafter be made for the process in which light is output from a lamp and is formed into image light. White light produced by a lamp 31 is gathered by a reflector 32 and is emitted toward a first lens array 34 through a concave lens 33. The first lens array splits the incident pencil of light into a plurality of pencils of light and directs them so that they efficiently pass through a second lens array 35 and a polarization converter 36. Each of lens cells constituting the second lens array 35 projects the image of the associated one of lens cells of the first lens array 34 onto display devices 37, 38, and 39 for three primary colors of red, green, and blue (R, G, and B). The projected images of the lens cells of the first lens array 34 are superimposed on the display devices 37, 38, and 39 by condenser lenses 40, 41, 42, 43, a first relay lens 44, and a second relay lens 45. Mirrors 46, 47, 48, and 49 are provided for changing the direction of the light in the optical system. In the process, dichroic mirrors 50 and 51 separate the white light emitted by the light source into three primary colors of R, G, and B, and then each of them is irradiated to the associated display devices 37, 38, and 39. Images on the display devices 37, 38, and 39 are color-combined by a dichroic-cross-prism 52 and then projected onto a screen 54 by a projection lens 53 to form a large-screen image. Also, the first relay lens and the second relay lens are provided for compensating the longer optical path of the light from the light source to the display device 39 than the optical path to the display devices 37 and 38. The condenser lenses 41, 42, and 43 are provided for reducing the divergence of the light rays after they pass through the display devices 37, 38, and 39, respectively, to achieve efficient projection by the projection lens.

As described above, the reflecting membrane according to the present invention is provided for the reflector 32, the mirrors 46, 47, 48, and 49, and the dichroic mirrors 50 and 51 to increase the reflective index. This can improve the light use efficiency and reduce the output power of the light source to save energy.

The output light passes the vessel of the lamp 31, the various lenses including the condenser lenses 40, 41, 42, and 43, the relay lenses 44 and 45, the lens arrays 34 and 35, the polarization converter 36, display devices 37, 38, and 39, and the dichroic-cross-prism 52. Therefore, the anti-reflecting membrane according to the present invention can be provided for the light-passing surfaces of them, that is, both of the light-receiving surface and the light-exiting surface to reduce the reflection on the surfaces to improve the light transmittance. The anti-reflecting membrane according to the present invention can also be provided for the light-transmitting surfaces of the dichroic mirrors 50 and 51 to reduce the reflection on the surfaces to improve the light transmittance.

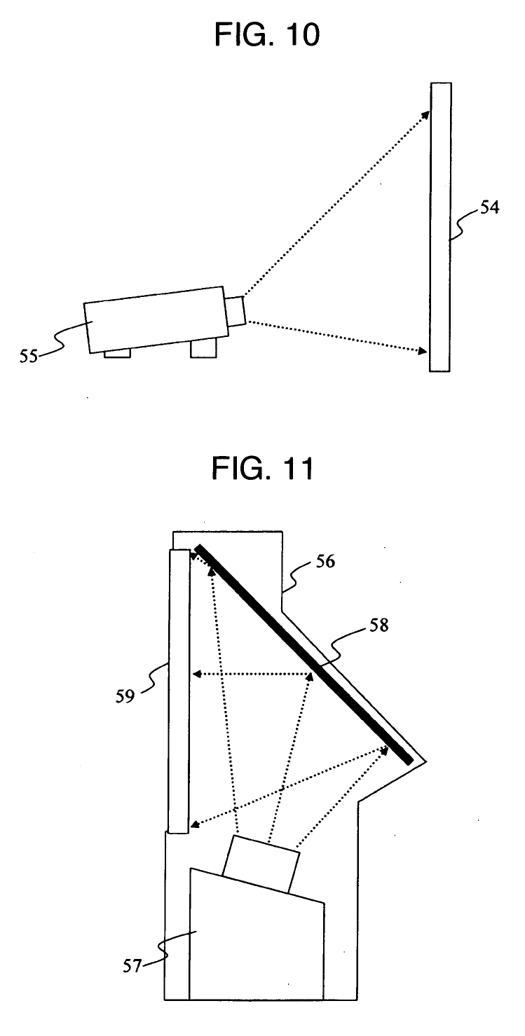

FIG. 10 is a schematic diagram showing an image forming apparatus of a front projection type with the abovementioned optical system. An optical image output from an optical unit 55 (corresponding to the portion of the optical system in FIG. 9 excluding the screen) is projected onto a screen 54.

FIG. 11 is a schematic diagram showing an optical system of a projection type display apparatus. A housing 56 contains an optical unit 57 (corresponding to the portion of the optical system in FIG. 9 excluding the screen) and a back-face mirror 58. Light emitted from the optical unit 57 is turned by the back-face mirror 58 and projected onto a screen 59. In this manner, an image is displayed on the screen 59. The anti-reflecting membrane according to the present invention can be provided for both light-transmitting surfaces of the screen 59 to reduce the reflection on the surfaces and to improve the light transmittance.

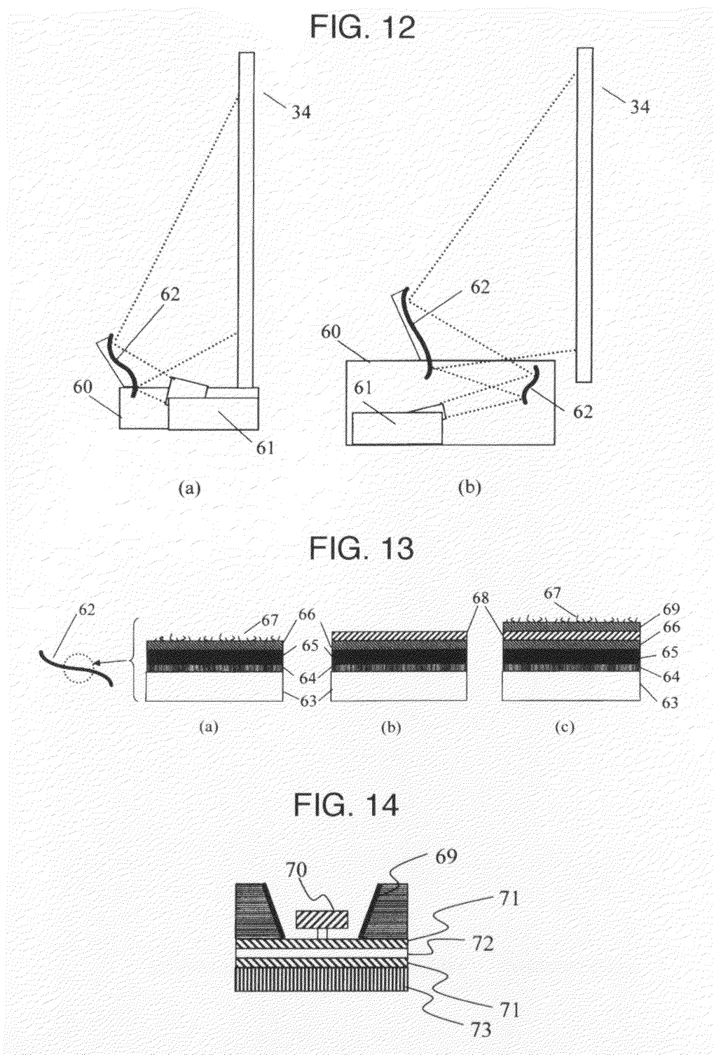

FIG. 12 is a schematic diagram showing a display apparatus according to the present invention. In the apparatus, an optical image is output from an optical unit 61 in a housing 60, is controlled for a desired projection direction and enlarged simultaneously by a curved mirror (free-curve mirror) 62, and then is projected onto a screen 54. In other words, the free-curve mirror 62 has integrated two functions of the turning of the optical image by a planar mirror and the enlargement of the optical image by a lens. FIG. 12(a) shows a structure in which the optical unit is integral with the screen, while FIG. 12(b) shows a structure in which the optical unit is separated from the screen. A single or a plurality of free-curve mirrors are used in the apparatuses. The display apparatus of this type can enlarge an optical image with an extremely short projection distance to allow use in limited space.

The free-curve mirror for projecting the optical image onto the screen is placed on the outermost side of the optical system of the projector and may be touched by a hand or rubbed to wipe dirt therefrom, so that it needs high physical strength. Thus, the following contrivance is provided for the free-curve mirror.

FIG. 13 is a schematic diagram showing a section of the free-curve mirror.

First, the structure of FIG. 13(a) is described. A free-curve mirror 62 includes a hard layer 64 on a base material 63. Since the free-curve mirror 62 has a complicated shape, the base material 63 made of polycarbonate resin or polyethylenetelephthalate resin is more easily shaped than glass or metal. However, the base material 63 made of organic resin is softer than glass or the like and is easily dented when it is pushed by a sharp tip. The dent causes deformation of the surface shape of the mirror to make it impossible to project a desired optical image. To address this, the hard layer is provided to prevent such a dent in the base material 63. A reflecting layer 65 is formed thereon. A low-refractive-index layer 66 made of silicon oxide is formed on the reflecting layer 65 to protect the reflecting layer 65 from shock or rubbing and transmit visible light. A soil-resistant layer 67 is formed thereon to provide soil resistance. The soil-resistant layer 67 is formed with a liquid-repellent agent for use in the soil-resistant treatment of the low-refractive-index membrane 66, that is, a material including a perfluoropolyether chain, a perfluoroalkyl chain, or a fluoroalkyl chain, and including an alkoxysilane residue at the end. This has a characteristic of tightly binding to the surface of silicon oxide. Since the soil-resistant layer 67 has lubrication and is particularly effective against rubbing due to the perfluoroalkyl chain or the fluoroalkyl chain.

In the structure of FIG. 13(b), a low-refractive-index layer 66 and a high-refractive-index layer 68 are stacked on a reflecting layer 65. The two layers serve as an enhanced reflecting membrane, so that the structure provides a higher reflective index than that of the structure of FIG. 13(a).

In the structure of FIG. 13(c), a low-refractive-index layer 69 and a soil-resistant layer 67 are stacked on the structure of FIG. 13(b). This provides a free-curve mirror having the soil resistance similar to that of FIG. 13(a) and the high reflective index similar to that of FIG. 13(b).

Next, each of the layers will be described.

The hard layer is preferably made of acryl based resin, and is desirably formed of a polymer of a cross-linker such as pentaerythritol to improve the hardness. The usable resins other than this are a melamine based resin and a silicon based resin. While a thicker membrane is less dented, an extremely thick membrane hardly maintains the planarity and may affect the shape of the base material. In the circumstances, the membrane thickness is preferably 0.1 to 20 μm.

The reflecting layer is formed of the reflecting membrane according to the present invention, or a material used for a typical mirror such as aluminum, silver, and chromium. In an environment susceptible to salt damage such as near the sea and in a hotel with a hot spring, or in an environment with a high concentration of hydrogen sulfide, metal such as aluminum and silver is easily corroded. As a result, the reflective index is reduced. In this regard, the reflecting membrane according to the present invention is originally formed of oxides, so that it is hardly corroded in the environment as described above and the reflective index thereof is little reduced.

The low-refractive-index layer, the high-refractive-index layer, and the soil-resistant layer are as described above.

Liquid Crystal Display

The reflecting membrane according to the present invention is effectively used as a reflecting layer of a light emitting device unit in a liquid crystal display. FIG. 14 is a schematic diagram showing the light emitting device unit. A reflecting membrane 69 according to the present invention is formed in the light emitting device unit. A light emitting diode tip 70 is provided as a light source and is supplied with power from a lead frame 72 sandwiched between insulating layers 71. A heat-radiating substrate 73 is provided below the insulating layers to cause the heat produced by the unit to escape. Even with the heat dissipation, the temperature rises to approximately 100° C. after continuous lighting for 12 hours. However, the reflecting layer according to the present invention has high heat resistance, so that it is little modified at that temperature and the reflective index of the reflecting membrane 69 is hardly reduced.

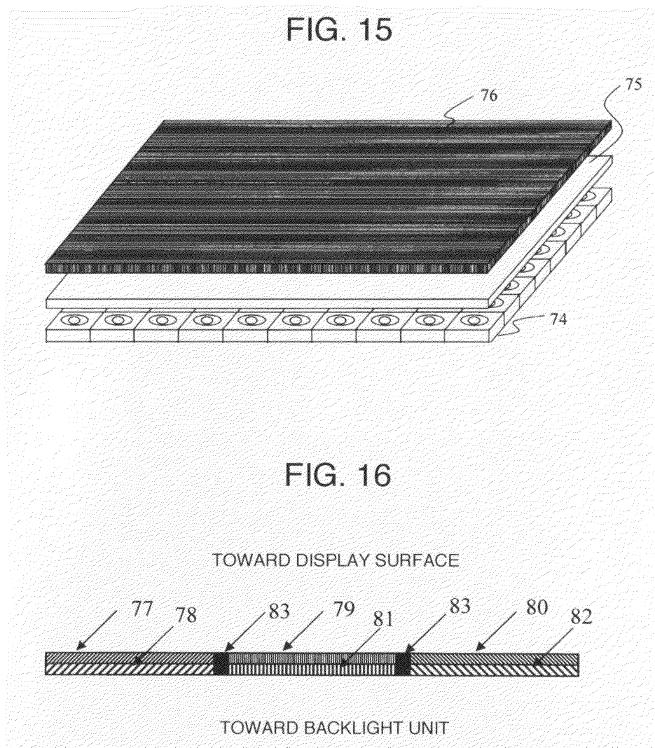

FIG. 15 shows a display apparatus in which the light emitting device unit is used. A plurality of the light emitting device units 74 are arranged to constitute a light source for the display apparatus. A group of optical materials 75 (a diffusion plate, a prism sheet and the like, although not shown in detail) is placed thereon, and a non-light-emitting display panel 76 (a liquid crystal display panel in this case) is provided thereon. Although not shown in detail, the non-light-emitting display panel 76 is formed of a back-face polarizer, a liquid crystal layer, a color filter layer, a front-surface polarizer and the like.

In addition, the reflecting membrane according to the present invention formed of a multi-layer structure including layers with the same thickness as described above serves as a dichroic mirror to reflect light in a particular wavelength range and transmit light in the other particular wavelength ranges. FIG. 16 is a schematic diagram showing a color filter in which the reflecting layer according to the present invention is used. Below an R filter 77, a reflecting layer 78 is provided which transmits light transmitted through the R filter 77 and reflects light transmitted through G and B filters 79 and 80. The light reflected by the reflecting layer 78 is directed toward a reflecting membrane of a backlight unit, diffused by the reflecting membrane, and transmitted through the G filter 79 the B filter 80. When the reflecting layer is not present, the R filter 77 absorbs the light transmitted through the G and B filters. However, with the reflecting layer 78 according to the present invention, the light is reflected before absorption by the R filter 77, is diffused by the reflecting membrane of the backlight unit, and some of the light is transmitted through the G and B filters 79 and 80, thereby enhancing the use efficiency of light form the light source. This can reduce the light amount from the backlight unit and accordingly reduce the power consumption, which is effective from the viewpoint of power savings and resource savings. For the other filters, in a similar manner, reflecting layers (a reflecting layer 81 below the G filter 79 for transmitting light transmitted through the G filter 79 and reflecting light transmitted through the R and B filters 77 and 80 and a reflecting layer 82 below the B filter 80 for transmitting light transmitted through the G filter 80 and reflecting light transmitted through the R and G filters 77 and 79) direct light, which would otherwise be absorbed by the filters, toward the reflecting membrane of the backlight unit, and the light is returned to the color filters, thereby further reducing power consumption.

Black matrixes 83 are present between the R, G, and B filters. The color filter may be formed only of the reflecting layer according to the present invention without using the R, G, or B filter. The provision of the R, G, and B filters tends to improve the purity of colors in the wavelength regions in which light is transmitted.

### 2. Equipment for Architectural Structure

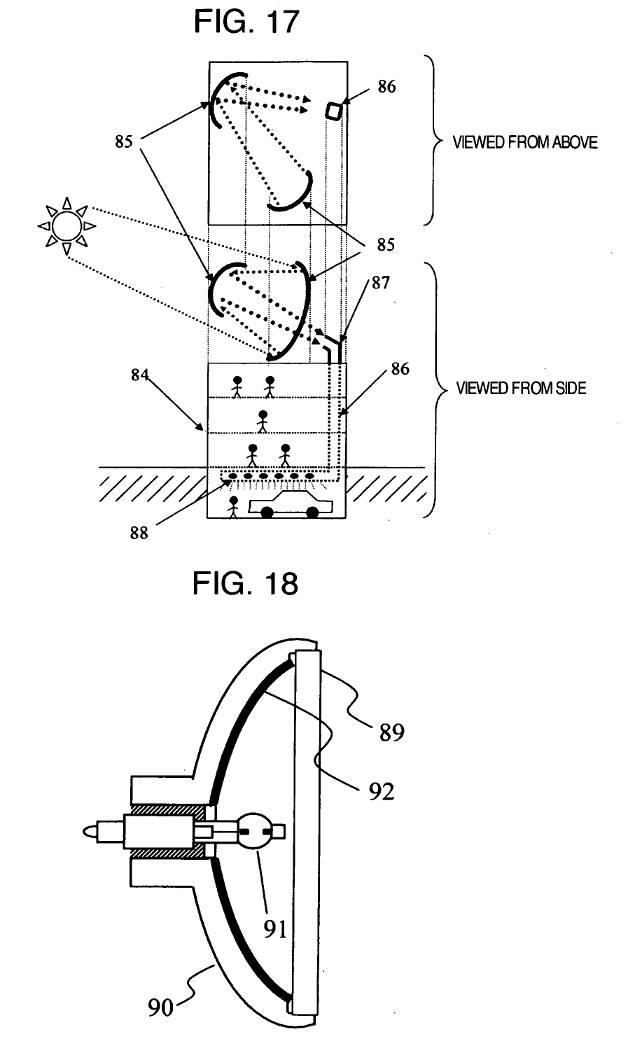

Since the reflecting membrane according to the present invention can be formed by a coating, it can be formed on an odd-form member. FIG. 17 is a schematic diagram showing a light conduction system which is one example of building equipment in which the reflecting membrane is used. A curved mirror 85 is provided on the roof of a building 84 to collect sunlight to a light conduction part 87 of a light-guide tube 86. The reflecting membrane according to the present invention is formed on the inner surface of the light-guide tube 86. Sunlight introduced to the light conduction part 87 travels in the light-guide tube 86 while being reflected by the inner surface thereof and then exits from a light-exit part 88. This configuration allows the sunlight to be directed to the underground of a house. The light guiding can be performed in an office building, and in a site away from a window through which external light passes, not limited to the underground. The light-guide tube 86 needs to have the reflecting membrane formed inside, but it is difficult to form the membrane therein with a vacuum process such as vapor deposition. Since the reflecting membrane according to the present invention can be formed with coating, the reflecting membrane can be formed with spray coating or the like inside a thick light-guide tube or with dip coating inside a thin light-guide tube.

### 3. Others

The reflecting membrane according to the present invention can be utilized as a reflecting membrane for a vehicle lamp unit or is effectively formed as an enhanced reflecting membrane on a reflecting membrane of a lamp unit which originally has the reflecting membrane. FIG. 18 is a schematic diagram showing the vehicle lamp unit. The lamp unit is formed of a front protecting cover 89 and a housing 90. A lamp 91 is fixed to the housing 90. A reflecting membrane 92 is formed on the inner surface of the housing 90. Part of exiting light from the lamp 91 that is not directed toward the protecting cover 89 is reflected by the reflecting membrane 92 and is caused to exit in the direction of the protecting cover 89. When the lamp unit originally has a reflecting membrane formed with vapor deposition or the like, the reflecting membrane according to the present invention can be formed thereon as the enhanced reflecting membrane to improve the reflective index to increase the exiting light amount from the protecting cover 89. A less power is required to provide a certain amount of exit light, so that battery is less exhausted to save energy.

### (A) Applicable Products in Which Anti-Reflecting Membrane is Used

Applicable products in which the anti-reflecting membrane is used include a greenhouse, an optical recoding medium, a display apparatus, and a solar energy converting device. Description will be made for each of them.

### 1. Greenhouse

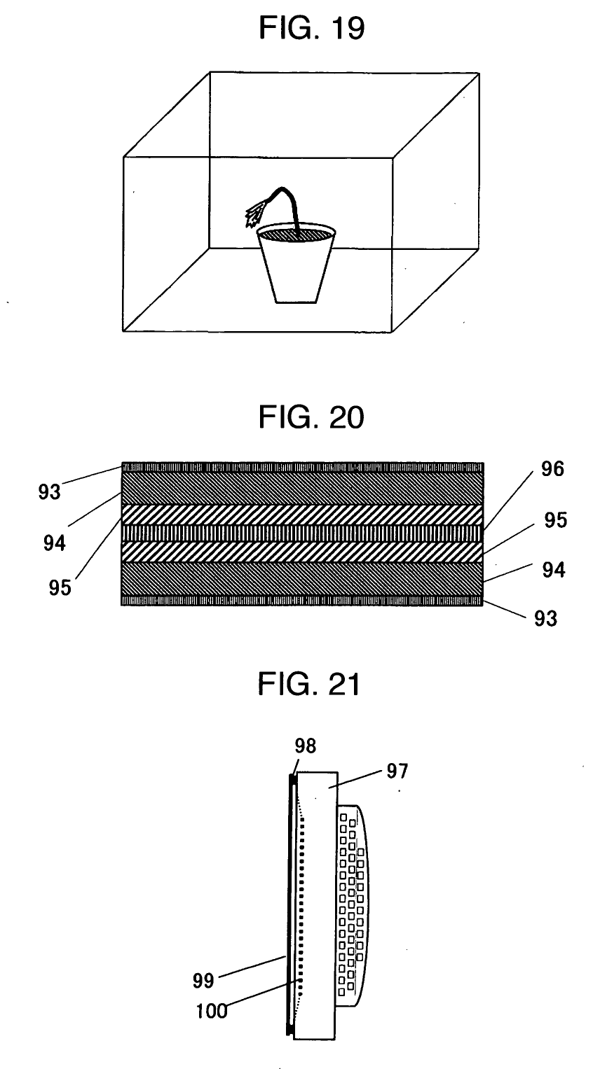

A container or a building of a greenhouse for achieving stable and rapid growth of plants and the like has a transparent wall or roof for letting sunlight in. However, a wall material of glass or acrylic resin reflects approximately 8% of the sunlight on its surface, so that only approximately 92% of the sunlight enters the greenhouse. The anti-reflecting membrane according to the present invention (having an average reflective index of 0.5% in a wavelength region from 400 to 700 nm) is formed on both surfaces of the roof and the wall to reduce the reflective index in the greenhouse. FIG. 19 is a schematic diagram showing the greenhouse. The formation of the anti-reflecting membrane reduces the reflective index to allow approximately 99% of the irradiated light to enter the greenhouse, thereby promoting the growth of plants. Since the anti-reflecting membrane according to the present invention has a characteristic in which dirt including dust is hardly attached to the surface due to its low resistance, so that it achieves improved light transmittance to enhance visibility even at a low humidity in winter or in an environment with many dust particles. The liquid-repellency given to the anti-reflecting membrane increases the soil resistance, which also improves the light transmittance to promote the growth of plants.

### 2. Recording Medium

Light at a wavelength of 780 nm is used for recording and reproduction of CDs and DVDs. For DVDs, however, light at a wavelength of 405 nm is beginning to be used recently for improving the recording density. When a disk is manufactured by using a substrate with a high reflective index of light, it is necessary to use light of high intensity in recording and reproduction. To increase the irradiation intensity without changing the output of a laser, the irradiation time of light for each pit may be increased, but this is disadvantageous in recording and reproduction at high speed. A reduction in the reflective index of light at wavelengths of interest on the disk surface leads to an increase in the amount of light reaching a recording layer, which serves one of techniques to enable the recording and reproduction at high speed.

Since the anti-reflecting membrane according to the present invention can be provided to reduce the amount of light necessary for recording and reproduction for each pit, a lower light intensity is required of the light source when recording and reproduction are performed at the same speed as conventional one. When the same light intensity as conventional one is used, recording and reproduction can be performed at a higher speed.

FIG. 20 is a section view showing a DVD disk in which the anti-reflecting membrane according to the present invention is used. The DVD disk includes a polycarbonate substrate 94 on which an anti-reflecting membrane 93 according to the present invention is formed. A protecting layer 95 and a recording layer 96 are formed over the substrate 94. Test data was written to the disk and then reproduced with a light intensity of 0.5 mW which is a half of a conventional intensity. The data was read accurately. If data is similarly reproduced from a disk in which the anti-reflecting membrane according to the present invention is not used, a read error occurs. This is because significant reflection on the surface reduces the amount of light reaching a light-receiving part of a reproduction apparatus. Light at 1 mW is typically used and thus reading is performed with no problems, but the read-out light at the half intensity causes the abovementioned problem. It is contemplated that since the DVD disk on which the anti-reflecting membrane according to the present invention is formed has extremely low reflection, most of the read-out light can be input to the light-receiving part of the reproduction apparatus to reduce the possibility of the abovementioned problem.

Thus, the use of the membrane according to the present invention has been confirmed to provide the high-sensitivity optical recording medium from which data can be read out at a half light intensity of typical read-out light for a DVD.

### 3. Display Apparatus

In most of display apparatuses placed in a bright environment, specifically a CRT display, a liquid crystal display, a plasma display, an organic electroluminescence display, a cellular phone, a PDA and the like, the surrounding objects appear on a screen serving as a display part of the display apparatus and are superimposed on a displayed image to significantly reduce visibility. This is because the screen reflects visible light. The anti-reflecting membrane according to the present invention can be formed to reduce the superimposition.

Liquid Crystal Display

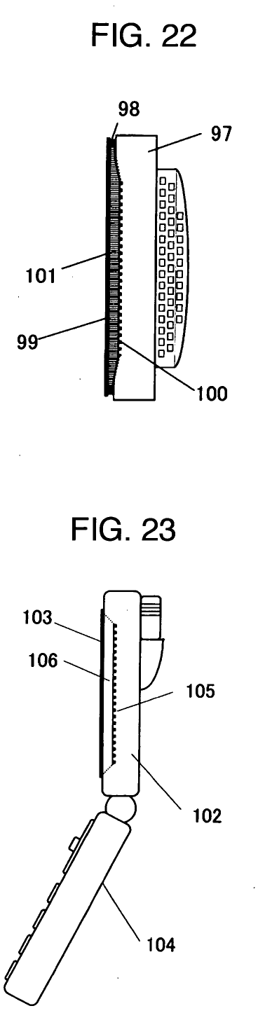

Application of the present invention to a liquid crystal display will be described with reference to FIGS. 21 and 22 which are schematic diagrams showing a display apparatus according to the present invention when viewed from above. A 32-inch diagonal liquid crystal display is described, but the present invention is applicable to a liquid crystal display of a different size by changing the size and the like of a glass plate.

The anti-reflecting membrane according to the present invention is formed on both surfaces of a glass plate having vertical and horizontal dimensions of 460 mm and 770 mm, respectively, and a thickness of 3 mm.

Next, two 32-inch diagonal liquid crystal displays are prepared. The glass plate having the anti-reflecting membrane formed on both surfaces is attached to the outermost surface of the panel of one of the displays as shown in FIG. 21. This serves as one of liquid crystal displays according to the present invention. A liquid crystal display 97 with a glass plate 99 having the anti-reflecting membrane according to the present invention formed on both surfaces so that a spacer 98 having a height of 1 mm is sandwiched between them is used. A polarizer 100 is placed on the outermost surface of the liquid crystal display 97. The polarizer 100 is of a type having a roughened surface to scatter reflected light.

Next, as a comparative example, a glass plate having no anti-reflecting membrane formed thereon is attached to the other 32-inch diagonal liquid crystal display in a similar manner. The liquid crystal display to which the glass plate having the anti-reflecting membrane according to the present invention formed thereon was attached and the liquid crystal display as the comparative example to which the glass plate having no anti-reflecting membrane formed thereon was attached were placed near a window such that their screens were irradiated with sunlight at the same level. As a result, in the liquid crystal display to which the glass plate having no anti-reflecting membrane formed thereon was attached as the comparative example, the superimposition of surrounding objects on the screen was not ignorable. In contrast, in the liquid crystal display to which the glass plate having the anti-reflecting membrane according to the present invention formed thereon was attached, the anti-reflecting membrane prevents reflection of incident sunlight on the surface to reduce the superimposition of surrounding objects on the screen to a negligible level.

It is shown from the above that the liquid crystal display provided with the anti-reflecting membrane according to the present invention can display a sharp image since the superimposition of surrounding objects on the screen is almost prevented even when strong sunlight is incident.

Next, the liquid crystal display 97 shown in FIG. 22 will be described. The display 97 is provided by filling transparent organic resin (having a refractive index of 1.5) 101 between a polarizer 100 and a glass plate 99 sealed by a sealing part 98. This fills the interface between the polarizer 100 and the glass plate 99 to extremely reduce the reflective index of the filled surface. Since the anti-reflecting membrane according to the present invention is formed on the surface of the glass plate 99 opposite to the polarizer 100 that significantly reflects light, the superimposition is reduced and improved visibility is confirmed. While polyisobutylene is used as the transparent resin, a rubber-like resin at room temperature is easily filled between the polarizer 100 and the glass plate 99 such as a copolymer of ester methacrylate and ester acrylate having a long-chain alkyl group such as 2-ethylhexyl group at a side chain.

In this case, since the roughened surface is also filled with the resin, the polarizer 100 may be of a roughened type or a flat type. The glass plate 99 may have the anti-reflecting membrane on both surfaces or may have the anti-reflecting membrane on only one surface, that is, only on the outermost surface.

Cellular Phone

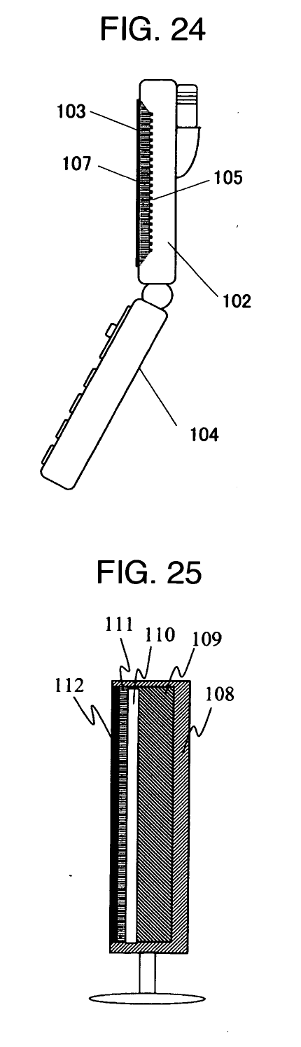

Next, the application of the present invention to a cellular phone will be described with reference to FIGS. 23 and 24 which are schematic diagrams showing the structures of cellular phones according to the present invention. Each of the cellular phones shown in FIGS. 23 and 24 is provided by removing an acrylic plate 103 placed on the outermost surface of a display part, forming the anti-reflecting membrane according to the present invention on both surfaces of the acrylic plate 103, and then disposing the plate 103 again in place. Each of cellular phones provided with the acrylic plate 103 having the anti-reflecting membrane according to the present invention formed on the outermost surface of the display part 102 is operated through an operation part 104. The cellular phone in FIG. 23 includes a gap 106 between a polarizer 105 and the acrylic plate 103 having the anti-reflecting membrane formed thereon. The cellular phone in FIG. 24 includes a resin filling layer 107 between a polarizer 105 and the acrylic plate 103 having the anti-reflecting membrane formed thereon. The resin filing layer 107 is made of polyisobutylene.

The display parts of the two types of cellular phones according to the present invention and of a conventional cellular phone with no anti-reflection treatment performed were directly exposed to sunlight. The conventional cellular phone with no anti-reflection treatment performed was significantly affected by superimposition of surrounding scenery on a display part to cause difficulty in image recognition. On the other hand, in the cellular phone according to the present invention with the anti-reflection treatment performed on the acrylic plate, superimposition of surrounding scenery on the display part was not significantly produced and thus image recognition was easily achieved. It is shown from the above that the cellular phone having the anti-reflecting membrane according to the present invention allows easy image recognition since significant superimposition of surrounding scenery does not occur when the display part is directly exposed to sunlight. The present invention is not limited to cellular phones but is applicable to PDAs and the like having a display part of a similar structure to provide similar effects. Thus, the portable display terminal having the anti-reflecting membrane according to the present invention has the display part with high visibility in which significant superimposition of surroundings does not occur outdoors in direct sunlight.

Plasma Television

Next, application of the present invention to a plasma television set will be described with reference to FIG. 25 which is a schematic diagram showing a section of a plasma television set according to the present invention. A housing 108 includes a panel 109 for forming an image, and a glass plate 111 is mounted so that a gap 110 is sandwiched between the glass plate 111 and the panel 109. The glass plate 111 is removed and an anti-reflecting membrane 112 according to the present invention is formed on the surface thereof. The glass plate 111 having the anti-reflecting membrane 112 formed thereon is mounted so that the surface having the anti-reflecting membrane 112 formed thereon faces the front. In this manner, the plasma television set according to the present invention is provided.

The plasma television set provided with the glass plate 111 having the anti-reflecting membrane 112 formed thereon according to the present invention and a conventional plasma television set were placed near a window such that their screens were irradiated with sunlight at the same level. As a result, in the conventional plasma television, superimposition of surroundings on a screen was not ignorable. In contrast, in the plasma television set provided with the glass plate 111 having the anti-reflecting membrane 112 formed thereon according to the present invention, the anti-reflecting membrane prevents reflection of incident sunlight on the surface to reduce superimposition of surroundings on the screen to a negligible level.

It is shown from the above that the plasma television set provided with the anti-reflecting membrane according to the present invention can display a sharp image since the superimposition of surroundings on the screen is almost prevented even when strong sunlight is incident.

The present invention is also applicable to EL displays. In this case, formation of the anti-reflecting membrane according to the present invention on the outermost surface of a substrate can reduce the reflective index to increase the transmittance to improve luminance, thereby requiring a lower amount of light emission. This advantageously increases the life of the light emitting element and saves energy.

### 4. Solar Energy Converting Module

In a solar energy converting module, the present invention can be applied to improve use efficiency of light by reducing reflection from the surface of a light-receiving part to increase the transmittance.

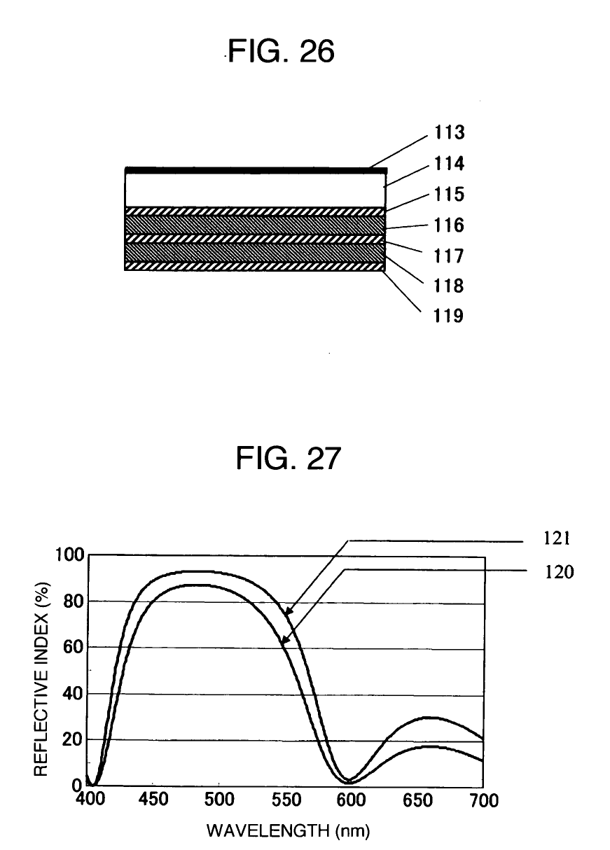

The anti-reflecting membrane according to the present invention is formed on the surface of the solar energy converting module. FIG. 26 is a schematic diagram showing the structure of the solar energy converting module. Below a glass substrate 114 having an anti-reflecting membrane 113 formed thereon, a surface electrode 115, an upper photon-electron converter layer 116, middle transport electrode 117, a bottom photon-electron converter layer 118, and a back electrode 119 are formed.

The solar energy converting module provided with the anti-reflecting membrane according to the present invention and a conventional solar energy converting module with no anti-reflecting membrane according to the present invention formed thereon were placed so that they were irradiated with sunlight at the same level, and then the power generation amount was measured. As a result, the solar energy converting module provided with the anti-reflecting membrane according to the present invention showed a power generation amount approximately 10% larger than that of the conventional module.

The average reflective index at wavelengths from 400 to 700 nm was determined for the glass substrate having the anti-reflecting membrane according to the present invention formed thereon and a glass substrate with no anti-reflecting membrane formed thereon. The glass substrate with no anti-reflecting membrane formed thereon showed 10%, while the glass substrate having the anti-reflecting membrane formed thereon showed 0.5%. It is thought from the above that the power generation amount is improved since the photon-electron converter layer can take the sunlight without reflection.

It is shown from the above that the solar energy converting module having the anti-reflecting membrane according to the present invention formed thereon can generate power at high efficiency due to low reflection on the surface of the glass substrate.

As described above, it is determined that the reflecting membrane, the enhanced reflecting membrane, and the anti-reflecting membrane according to the present invention are significantly effective in applications such as the optical products and the products with light utilization.

### EXAMPLES

The reflecting membrane and the anti-reflecting membrane applicable to the abovementioned products will be specifically described in terms of the membrane forming method and the like in the following examples, but the present invention is not limited to those examples.

Examples 1 to 4 show the method for forming the reflecting membrane (including the enhanced reflecting membrane) according to the present invention. Examples 5 and 6 show the method for forming the anti-reflecting membrane according to the present invention. In Examples, a glass plate is used as the base material. The base material and the size may be changed or the membrane thickness may be controlled as appropriate to allow application to the abovementioned products.

### Example 1

First, the method for forming the reflecting membrane on the glass plate will be described.

### (1) Pretreatment of Coating Application

A glass plate having a vertical dimension of 100 mm, a horizontal dimension of 100 mm, a thickness of 1.1 mm, and a refractive index of 1.52 was irradiated with ultraviolet rays by a low-pressure mercury lamp. The irradiation dose was 10 mW for five minutes to result in a contact angle of 10° or less between the glass plate surface subjected to the ultraviolet irradiation and water. The contact angle between the glass plate surface before the ultraviolet irradiation and water was 30 to 35°.

### (2) Preparation of Low-Refractive-Index Membrane Coating Material

Silicasol (phosphoric acid-acidified, solvent containing a water to ethanol ratio of 1:4, 5 wt % of alkoxysilane polymer contained is silicasol) (80 parts by weight), a dispersant of silicon oxide as inorganic oxide particles (an average particle diameter of 10 to 50 nm, 10 wt % of inorganic oxide particles contained in the dispersant) (120 parts by weight), and 2-propanol (280 parts by weight) were mixed to prepare a coating (hereinafter referred to as a low-refractive-index membrane coating material) for forming the low-refractive-index membrane. The boiling point of the coating material was 83° C.

### (3) Preparation of High-Refractive-Index Membrane Coating Material

Tetra-n-butoxytitanate as titaniasol (40 parts by weight), smectite SAN manufactured by OP CHEMICAL CO., LTD. as oilophilic smectite (3 parts by weight), and toluene as a solvent (600 parts by weight) were mixed to prepare a coating material (hereinafter referred to as a high-refractive-index membrane coating material) for forming the high-refractive-index membrane. The boiling point of the coating was 118° C.

### (4) Formation of Low-Refractive-Index Membrane

### 1. Coating Application

The low-refractive-index membrane coating material was applied to the glass plate subjected to the pretreatment (1) with spin coating. The spin coating was performed first at 350 rpm for five seconds and then at 1200 rpm for 20 seconds. The applied coating was almost uniformly spread over the glass plate in a visual check.

### 2. Heating

After the spin coating, the glass plate was immediately put in a constant temperature bath controlled at 160° C. and heated for 10 minutes. This changed silicasol into silicon oxide to complete heat curing. In this manner, the glass plate was provided which had the low-refractive-index membrane with a refractive index of 1.33 and a thickness of 90 nm formed on the surface.

### (5) Formation of High-Refractive-Index Membrane

### 1. Coating Application

The high-refractive-index membrane coating material was applied onto the low-refractive-index membrane with spin coating. The spin coating was performed first at 350 rpm for five seconds and then at 1800 rpm for 20 seconds. The applied coating material was almost uniformly spread over the glass plate in a visual check.

### 2. Heating

After the spin coating, the glass plate was immediately put in a constant temperature bath controlled at 100° C. and heated for 10 minutes. This changed titaniasol into titanium oxide to complete heat curing. In this manner, the glass plate having the high-refractive-index membrane with a refractive index of 1.79 and a thickness of 67 nm formed thereon was provided on the surface of the low-refractive-index membrane.

### (6) Formation of Multiple Layers

The operations of (4) and (5) were repeated to stack alternately the low-refractive-index membrane and the high-refractive-index membrane. The operation of (4) was finally performed to form, on one surface of the glass plate, a multi-layer membrane (the reflecting membrane according to the present invention) including six layers of the low-refractive-index membrane and five layers of the high-refractive-index membrane and having the low-refractive-index layer placed on the outermost surface.

### (7) Evaluation Test

The reflective index of the glass plate having the reflecting membranes according to the present invention formed thereon through the operations of (1) to (7) was measured. The results are shown in a graph of FIG. 27 in which the vertical axis represents the reflective index (%) and the horizontal axis represents the wavelength (nm). A curve 120 corresponds to the reflective index when the reflecting membrane according to the present invention is formed on one surface and shows that the reflecting membrane has the maximum reflective index of 87.4% at a wavelength of 483 nm.

Since the reflective index is 2% or less at or near wavelengths of 400 nm and 600 nm, it is obvious that the reflecting membrane has a characteristic as a dichroic mirror which shows a high reflective index only in a limited wavelength region.

### Example 2

The coating material prepared in Example 1 was used to alternately stack the high- and low-refractive-index membranes of which a total is ten (the membranes alternatively stacked by five high-refractive-index layers and five low-refractive-index layers) on the reflecting membrane formed in Example 1. The membranes were formed by reducing the number of rotations of spin coating so that the thickness of the high-refractive-index membrane was 84 nm and the thickness of the low-refractive-index membrane was 113 nm. The measurement of the reflective index of the glass plate showed that the reflective index was 60% or more in a region of 420 to 680 nm. It is shown that the stacking of the high-refractive-index membranes and the low-refractive-index membranes having different thicknesses can form the reflecting membrane having a high reflective index in a wide band.

### Example 3

The coating material prepared in Example 1 was used to form a multi-layer membrane similar to Example 1 (membrane including a stack of six low-refractive-index layers and five high-refractive-index layers) on the surface of the glass plate that did not have the reflecting membrane formed thereon in Example 1, although the other surface thereof had the reflecting membrane formed thereon. In this manner, the glass plate was provided which had the reflecting membrane according to the present invention formed on both surfaces.

The reflective index of the glass plate was measured. The results are also shown in FIG. 27. A curve 121 corresponds to the reflective index when the reflecting membrane according to the present invention is formed on both surfaces and shows that the reflecting membrane has the maximum reflective index of 93.3% at a wavelength of 483 nm.

Since the reflective index is 4% or less at or near wavelengths of 400 nm and 600 nm, it is clear that the reflecting membrane has a characteristic as a dichroic mirror which shows a high reflective index only in a limited wavelength region.

### Example 4

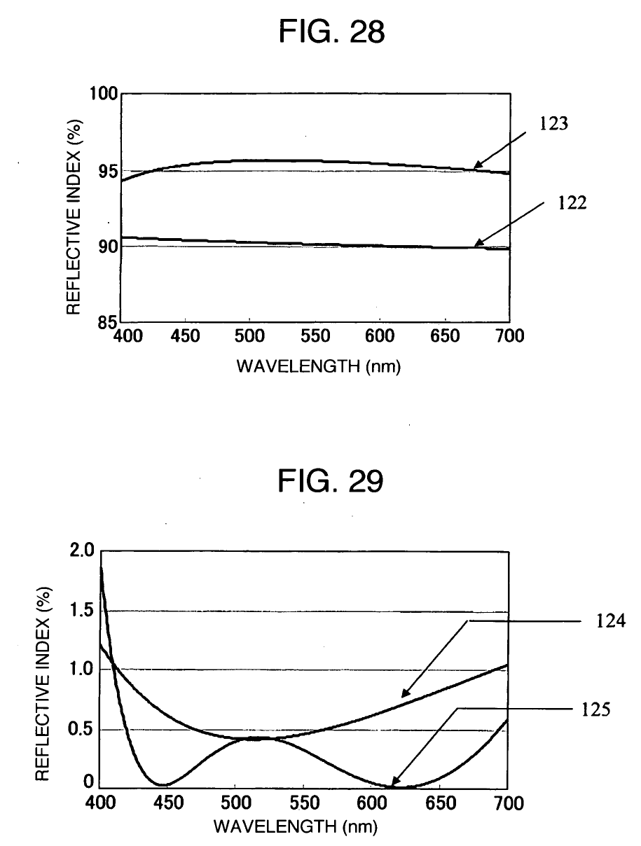

An aluminum thin membrane having a thickness of approximately 100 nm was formed on the glass plate with vapor deposition. FIG. 28 shows the result of measurement of the reflective index of the membrane. The vertical axis represents the reflective index (%) and the horizontal axis represents the wavelength (nm). A curve 122 corresponds to the reflective index of the aluminum thin membrane and shows a reflective index of approximately 90% in a region of 400 to 700 nm.

The low-refractive-index membrane coating and the high-refractive-index membrane coating prepared in Example 1 were alternately used to form three layers on the aluminum thin membrane (the low-refractive-index membrane having a refractive index of 1.33 and a thickness of 64 nm on the aluminum thin membrane, the high-refractive-index membrane having a refractive index of 1.77 and a thickness of 45 nm thereon, and the low-refractive-index membrane having a refractive index of 1.33 and a thickness of 13 nm on the outermost surface). The three layers of the stacked membranes served as the enhanced reflecting membrane among the reflecting membranes according to the present invention.

Since the formed membranes should be thinner than those in Example 1, the speed of spin coating in the application of the coating was changed to a slightly higher one.

In FIG. 28, a curve 123 corresponds to the reflective index of the aluminum thin membrane having the reflecting membrane according to the present invention formed thereon and shows a refractive index of approximately 95% in a region of 400 to 700 nm. It is shown from the 5% increase of the reflective index that the reflecting membrane according to the present invention serves as the enhanced reflecting membrane.

### Example 5

First, the method for forming the anti-reflecting membrane on the glass plate will be described.

### (1) Pretreatment of Coating Application

A glass plate having a vertical dimension of 100 mm, a horizontal dimension of 100 mm, a thickness of 1.1 mm, and a refractive index of 1.52 was irradiated with ultraviolet rays by a low-pressure mercury lamp. The irradiation dose was 10 mW for five minutes to result in a contact angle of 10° or less between the glass plate surface subjected to the ultraviolet irradiation and water. The contact angle between the glass plate surface before the ultraviolet irradiation and water was 30 to 35°.

### (2) Preparation of Low-Refractive-Index Membrane Coating Material

Silicasol (phosphoric acid-acidified, solvent containing a water-to-ethanol ratio of 1:4, 5 wt % of alkoxysilane polymer contained in silicasol) (70 parts by weight), a dispersant of silicon oxide as inorganic oxide particles (an average particle diameter of 10 to 50 nm, 10 wt % of inorganic oxide particles contained in the dispersant) (120 parts by weight), and 2-propanol (280 parts by weight) were mixed to prepare a coating material (hereinafter referred to as a low-refractive-index membrane coating material) for forming the low-refractive-index membrane. The boiling point of the coating was 83° C.

### (3) Preparation of High-Refractive-Index Membrane Coating Material

Tetra-n-butoxytitanate as titaniasol (35 parts by weight), smectite SAN manufactured by OP CHEMICAL CO., LTD. as oilophilic smectite (3 parts by weight), and toluene as a solvent (600 parts by weight) were mixed to prepare a coating material (hereinafter referred to as a high-refractive-index membrane coating material) for forming the high-refractive-index membrane. The boiling point of the coating was 118° C.

### (4) Formation of High-Refractive-Index Membrane

### 1. Coating Application

The high-refractive-index membrane coating application was applied to the glass plate subjected to the pretreatment (1) with spin coating. The spin coating was first performed at 350 rpm for five seconds and then at 1200 rpm for 20 seconds. The applied coating material was almost uniformly spread over the glass plate in a visual check.

### 2. Heating

After the spin coating, the glass plate was immediately put in a constant temperature bath controlled at 100° C. and heated for 10 minutes. This changed titaniasol into titanium oxide to complete heat curing. In this manner, the glass plate was provided which had the high-refractive-index membrane with a refractive index of 1.77 and a thickness of 149 nm formed on the surface.

### (5) Formation of Low-Refractive-Index Membrane

### 1. Coating Application

The low-refractive-index membrane coating was applied onto the high-refractive-index membrane with spin coating. The spin coating was performed first at 350 rpm for five seconds and then at 1200 rpm for 20 seconds. The applied coating was almost uniformly spread over the glass plate in a visual check.

### 2. Heating

After the spin coating, the glass plate was immediately put in a constant temperature bath controlled at 160° C. and heated for 10 minutes. This changed silicasol into silicon oxide to complete heat curing. In this manner, the glass plate having the two-layer membrane formed thereon was provided in which the low-refractive-index membrane with a refractive index of 1.31 and a thickness of 96 nm was formed on the surface of the high-refractive-index membrane. The two-layer membrane serves as the anti-reflecting membrane according to the present invention.

A glass plate having only the low-refractive-index membrane formed thereon as a single-layer anti-reflecting membrane was prepared and used for evaluation, later described.

### (6) Evaluation Test

The reflective index of the glass plate having the reflecting membranes according to the present invention formed thereon through the operations of (1) to (5) was measured. The results are shown in a graph of FIG. 29 in which the vertical axis represents the reflective index (%) and the horizontal axis represents the wavelength (nm). A curve 124 corresponds to the reflective index of the single-layer anti-reflecting membrane formed for comparison and shows the minimum reflective index of 0.42% at a wavelength of 513 nm and a reflective index of 0.5% or lower in a small region of 471 to 565 nm. The single-layer anti-reflecting membrane looks violet since the reflective index is low near 510 nm and is relatively high at approximately 400 to 450 nm and 600 to 700 nm to make the light in that region look mixed color, that is, violet.

In contrast, a curve 125 corresponds to the reflective index when the anti-reflecting membrane according to the present invention is formed and shows the two minimum reflective indexes of 0.012% at a wavelength of 622 nm and 0.027% at a wavelength of 447 nm and shows a reflective index of 0.5% or lower in a wide region of 440 to 698 nm which includes most of the visible region (400 to 700 nm). Thus, the membrane looks transparent with no color.

The glass plate having no anti-reflecting membrane formed thereon shows a reflective index of approximately 4% in the visible region of 400 to 700 nm.

It is shown from the above that the anti-reflecting membrane according to the present invention has an excellent anti-reflecting characteristic in a wide band.

### Example 6

First, the method for forming the anti-reflecting membrane on the glass plate will be described.

### (1) Pretreatment of Coating Application

A glass plate having a vertical dimension of 100 mm, a horizontal dimension of 100 mm, a thickness of 1.1 mm, and a refractive index of 1.52 was irradiated with ultraviolet rays by a low-pressure mercury lamp. The irradiation dose was 10 mW for five minutes to result in a contact angle of 10° or less between the glass plate surface subjected to the ultraviolet irradiation and water. The contact angle between the glass plate surface before the ultraviolet irradiation and water was 30 to 350.

### (2) Preparation of Low-Refractive-Index Membrane Coating Material

Silicasol (phosphoric acid-acidified, solvent containing a water-to-ethanol ratio of 1:4, 5 wt % of alkoxysilane polymer contained in silicasol) (80 parts by weight), a dispersant of silicon oxide as inorganic oxide particles (an average particle diameter of 10 to 50 nm, 10 wt % of inorganic oxide particles contained in the dispersant) (120 parts by weight), and 2-propanol (280 parts by weight) were mixed to prepare a coating material (hereinafter referred to as a low-refractive-index membrane coating material) for forming the low-refractive-index membrane. The boiling point of the coating material was 83° C.

### (3) Preparation of High-Refractive-Index Membrane Coating Material

Tetra-n-butoxytitanate as titaniasol (30 parts by weight), smectite SAN manufactured by OP CHEMICAL CO., LTD. as oilophilic smectite (5 parts by weight), and toluene as a solvent (600 parts by weight) were mixed to prepare a coating material (hereinafter referred to as a high-refractive-index membrane coating material) for forming the high-refractive-index membrane. The boiling point of the coating material was 118° C.

### (4) Formation of High-Refractive-Index Membrane

### 1. Coating Application

The high-refractive-index membrane coating material was applied to the glass plate subjected to the pretreatment (1) with spin coating. The spin coating was performed first at 350 rpm for five seconds and then at 1200 rpm for 20 seconds. The applied coating was almost uniformly spread over the glass plate in a visual check.

### 2. Heating

After the spin coating, the glass plate was immediately put in a constant temperature bath controlled at 100° C. and heated for 19 minutes. This changed titaniasol into titanium oxide to complete heat curing. In this manner, the glass plate was provided which had the high-refractive-index membrane with a refractive index of 1.66 and a thickness of 157 nm formed on the surface.

### (5) Formation of Low-Refractive-Index Membrane

### 1. Coating Application

The low-refractive-index membrane coating material was applied onto the high-refractive-index membrane with spin coating. The spin coating was performed first at 350 rpm for five seconds and then at 1200 rpm for 20 seconds. The applied coating material was almost uniformly spread over the glass plate in a visual check.

### 2. Heating

After the spin coating, the glass plate was immediately put in a constant temperature bath controlled at 160° C. and heated for 10 minutes. This changed silicasol into silicon oxide to complete heat curing. In this manner, the glass plate having the two-layer membrane was provided in which the low-refractive-index membrane with a refractive index of 1.33 and a thickness of 96 nm was formed on the surface of the high-refractive-index membrane. The two-layer membrane serves as the anti-reflecting membrane according to the present invention.

A glass plate having only the low-refractive-index membrane formed thereon as a single-layer anti-reflecting membrane was prepared and used for evaluation, later described.

### (6) Evaluation Test

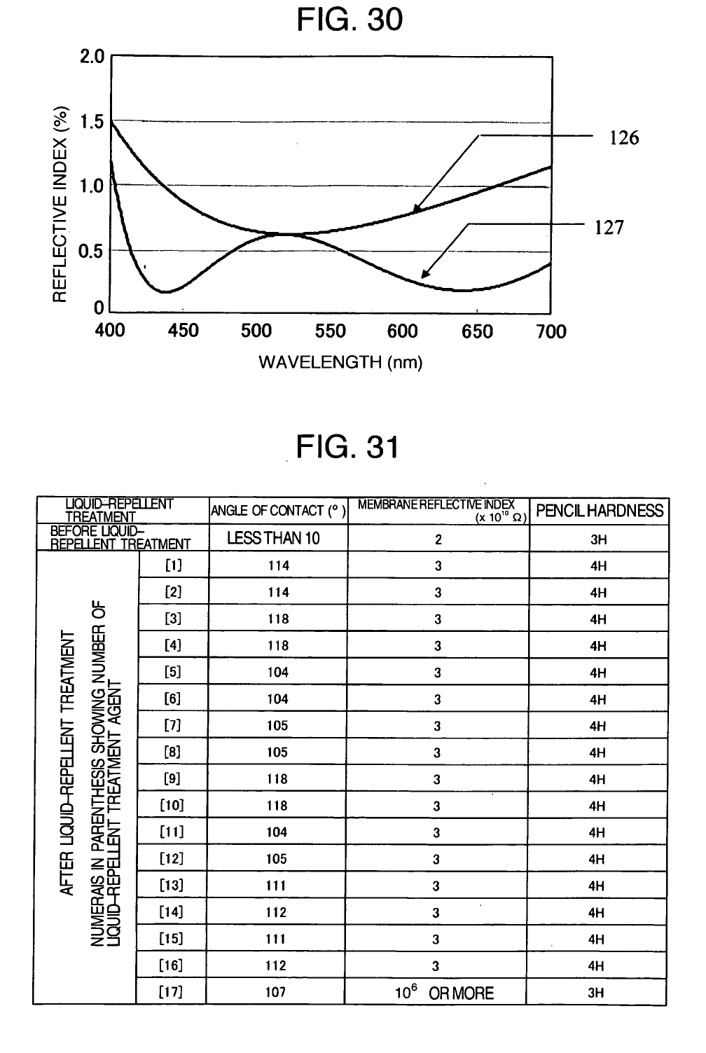

The reflective index of the glass plate having the reflecting membranes according to the present invention formed thereon through the operations of (1) to (5) was measured. The results are shown in a graph of FIG. 30 in which the vertical axis represents the reflective index (%) and the horizontal axis represents the wavelength (nm). A curve 126 corresponds to the reflective index of the single-layer anti-reflecting membrane formed for comparison and shows the minimum reflective index of 0.63% at a wavelength of 524 nm and a reflective index of 0.7% or lower in a small region of 480 to 575 nm. The single-layer anti-reflecting membrane looks violet since the reflective index is low near 520 nm and is relatively high at approximately 400 to 450 nm and 600 to 700 nm to make the light in that region look mixed color, that is, violet.

In contrast, a curve 127 corresponds to the reflective index when the anti-reflecting membrane according to the present invention is formed and shows the two minimum reflective indexes of 0.18% at a wavelength of 641 nm and 0.16% at a wavelength of 439 nm and shows a reflective index of 0.7% or lower in a wide region of 409 to 750 nm which includes most of the visible region (400 to 700 nm). Thus, the membrane looks transparent with no color.

It is shown from the above that the anti-reflecting membrane according to the present invention has an excellent anti-reflecting characteristic in a wide band.

### Example 7

Liquid-repellent treatment was performed on the glass plates in Examples 1 to 6 having the reflecting membrane or the anti-reflecting membrane according to the present invention formed thereon.

### (1) Preparation for Liquid-Repellent Treatment Agent

First, solutions of chemicals 1 to 16 at 0.5 wt % (Fluorinert PF-5080 manufactured by 3M used as a solvent) were prepared and used as the for liquid-repellent treatment agent. The prepared solutions of Compounds 1 to 16 at 0.5 wt % in PF-5080 are referred to as liquid-repellent treatment agents [1] to [16], respectively.

For comparison, a solution of CYTOP CTL-107M manufactured by ASAHI GLASS at 0.1% was used as a liquid-repellent treatment agent [17].

### (2) Liquid-Repellent Treatment Method

With Liquid-Repellent Treatment Agents [1] to [16]

The substrates were immersed in the liquid-repellent treatment agents for three minutes. The substrates were taken out and put in a constant temperature bath heated to 120° C. for ten minutes. The substrates were taken out and the surfaces thereof were rinsed with PF-5080 to remove the excess liquid-repellent treatment agent, thereby finishing the treatment.

With Liquid-Repellent Treatment Agent [17]

The substrates were immersed in the liquid-repellent treatment agent for three minutes. The substrates were taken out and put in a constant temperature bath heated to 120° C. for 30 minutes. The substrates were taken out to finish the treatment.

### (3) Evaluation of Liquid Repellency

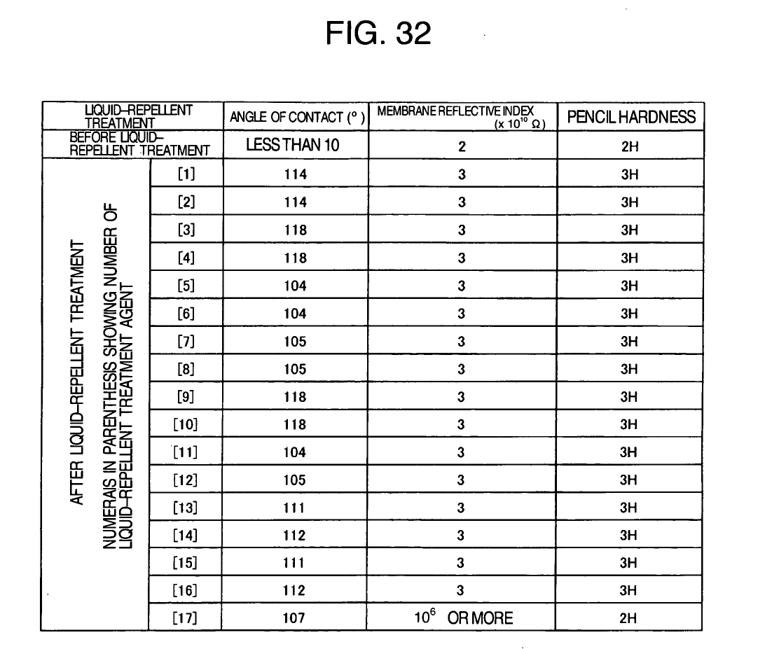

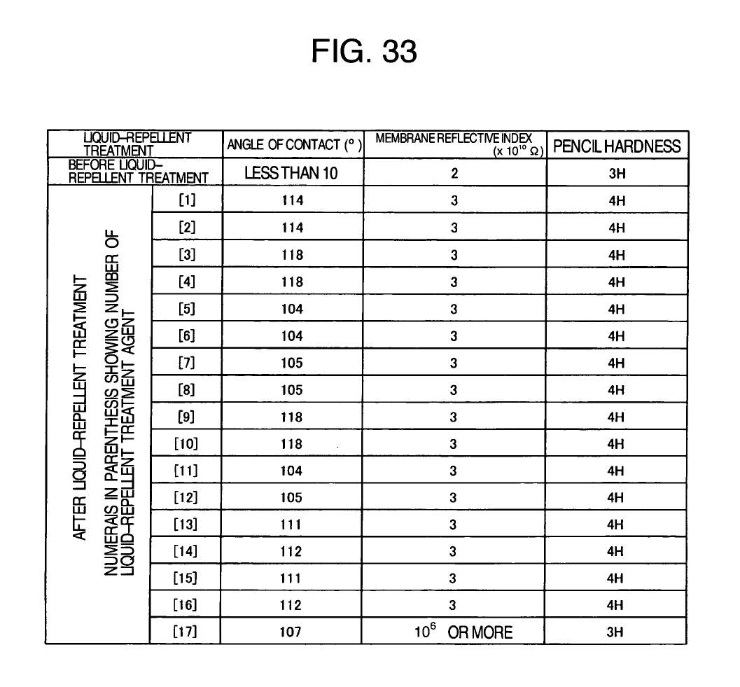

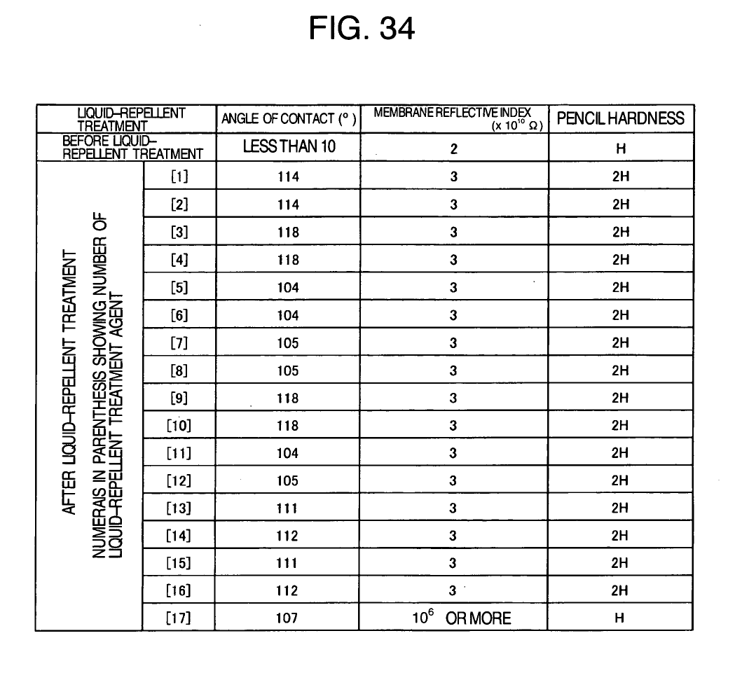

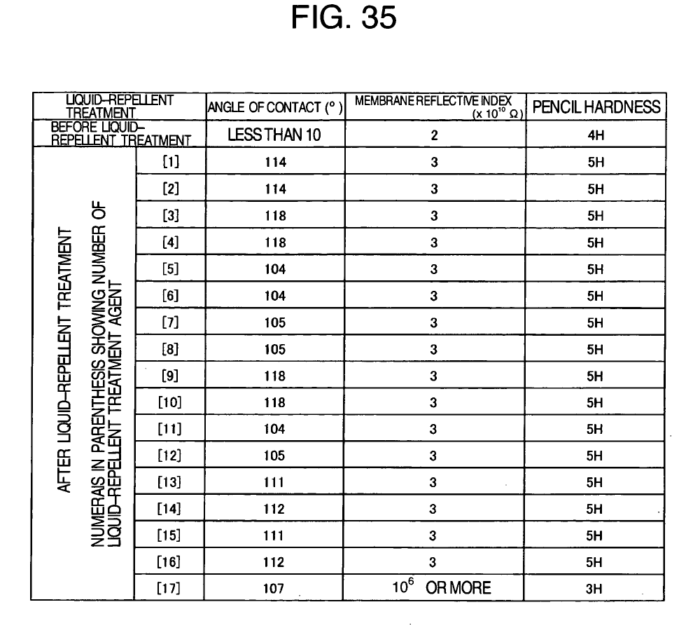

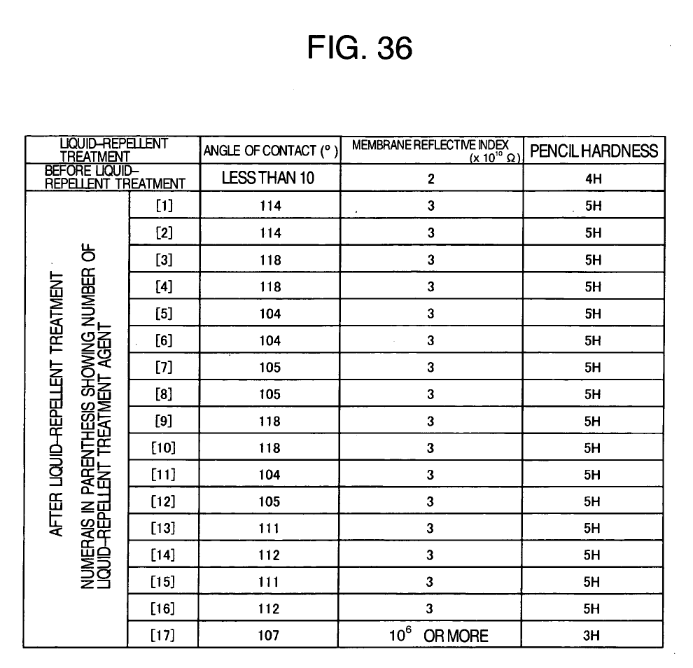

The liquid repellency of the surfaces of the substrates after the completion of the liquid-repellent treatment was evaluated in terms of the contact angle with water. The results are shown in tables of FIGS. 31 to 36. The contact angle with water before the liquid-repellent treatment and the pencil hardness before and after the liquid-repellent treatment are also shown.

All of the anti-reflecting membranes had the contact angles with water smaller than 100 before the liquid-repellent treatment. However, the liquid-repellent treatment increased the contact angles in all of the membranes. The refractive index and the reflective index did not show any observable changes before and after the liquid-repellent treatment. It is thus shown that the liquid-repellent treatment does not degrade the associated characteristics.

The substrates treated with the solution of CYTOP CTL-107M at 0.1% (liquid-repellent treatment agent [17]) showed an increased resistance. It is thought that this is because CYTOP CTL-107M covers substantially the entire surface of the anti-reflecting membrane but Compounds 1 to 16 do not cover all of the anti-reflecting membrane since the liquid-repellent fluoric chain bonds to some of the surface of the reflecting membrane or anti-reflecting membrane via the alkoxysilane residue. The increased membrane resistance makes the membrane become charged easily to cause the problem that more dirt and dust are attached thereto. Thus, Compounds 1 to 16 which do not increase the membrane resistance are preferable in that they can maintain the state of the membrane which attracts less dirt and dust. Regardless of the presence or absence of the liquid-repellent treatment, the reflecting membrane and the anti-reflecting membrane according to the present invention have lower resistances than the resistance of the glass plate (surface resistance rate: 10¹² to 10¹⁴Ω), so that the membranes according to the present invention can prevent dirt and dust from being attached as compared with simple glass.

It is shown from the above that the fluoric compounds having the alkoxysilane residue at the end are preferable in that they do not increase the membrane resistance even when they are given the liquid repellency.

Next, the pencil hardness of the membranes will be considered. The membranes subjected to the liquid-repellent treatment with Compounds 1 to 16 showed a higher pencil hardness than the untreated membrane, while the membranes treated with CYTOP CTL-107M showed the resistance to rubbing at the same level as that before the liquid-repellent treatment. It is obvious from the above that the liquid-repellent treatment improves the resistance to rubbing.

A comparison of the compounds used in the liquid-repellent treatment showed Compounds 1 to 4, 9, and 10 tend to provide a higher contact angle. Especially, Compounds 3, 4, 9, and 10 provided as high a contact angle as 100° or more in all of the membranes. Compounds 1 to 4, 9, and 10 have a perfluoropolyether chain, while the other compounds have a perfluoroalkyl chain or a fluoroalkyl chain. It is shown from the above that the liquid-repellent treatment with the compound having the perfluoropolyether chain can form the membrane having higher liquid repellency.

### Example 8

The high-refractive-index membrane coating was prepared in the same manner as Example 1 except that smectite SPN manufactured by COOP CHEMICALS CO., LTD. (3 parts by weight) was used instead of smectite SAN manufactured by COOP CHEMICALS CO., LTD. (3 parts by weight) as oilophilic smectite and was used to form the high-refractive-index membrane. The resultant membrane had a refractive index of 1.79.

The abovementioned high-refractive-index membrane coating material and the low-refractive-index membrane coating material used in Example 1 were used to form a multi-layer membrane in the same manner as Example 1. As a result, the provided reflective membrane had the maximum reflective index of 87.3% at a wavelength of 483 nm.

### Example 9

The high-refractive-index membrane coating was prepared in the same manner as Example 1 except that smectite SAN 316 manufactured by COOP CHEMICALS CO., LTD. (3 parts by weight) was used instead of smectite SAN manufactured by COOP CHEMICALS CO., LTD. (3 parts by weight) as oilophilic smectite and was used to form the high-refractive-index membrane. The resultant membrane had a refractive index of 1.79.

The abovementioned high-refractive-index membrane coating material and the low-refractive-index membrane coating material used in Example 1 were used to form a multi-layer membrane in the same manner as Example 1. As a result, the provided reflective membrane had the maximum reflective index of 87.3% at a wavelength of 483 nm.

### Example 10

The high-refractive-index membrane coating material was prepared in the same manner as Example 1 except that tetra-1-propoxytitanate (33 parts by weight) was used instead of tetra-n-butoxytitanate (40 parts by weight) as titaniasol and was used to form the high-refractive-index membrane. The resultant membrane had a refractive index of 1.79.

The abovementioned high-refractive-index membrane coating material and the low-refractive-index membrane coating material used in Example 1 were used to form a multi-layer membrane in the same manner as Example 1. As a result, the provided reflective membrane had the maximum reflective index of 87.4% at a wavelength of 483 nm.

### Example 11

The low-refractive-index membrane coating material was prepared in the same manner as Example 1 except that vinyltrimethoxysilane (10 parts by weight) was used instead of silicasol (80 parts by weight) and was used to form the low-refractive-index membrane. The resultant membrane had a refractive index of 1.33.

The abovementioned low-refractive-index membrane coating material and the high-refractive-index membrane coating material used in Example 1 were used to form a multi-layer membrane in the same manner as Example 1. As a result, the provided reflective membrane had the maximum reflective index of 87.4% at a wavelength of 483 nm.

It should be further understood by those skilled in the art that although the foregoing description has been made on embodiments of the invention, the invention is not limited thereto and various changes and modifications may be made without departing from the spirit of the invention and the scope of the appended claims.

1. An optical material comprising:
an optical material matrix;
an inorganic compound layer provided on the optical material matrix, wherein the inorganic compound layer is formed of a titanium compound having a hydrolysable residue and an oilophilic smectite, and having a refractive index higher than a refractive index of the optical material matrix; and
an another inorganic compound layer provided on the inorganic compound layer, wherein the another inorganic compound layer has a refractive index lower than the refractive index of the optical material matrix.

2. An optical material comprising:
an optical material matrix;
an inorganic compound layer provided on the optical material matrix, wherein the inorganic compound layer has a refractive index lower than a refractive index of the optical material matrix; and
an another inorganic compound layer provided on the inorganic compound layer, wherein the another inorganic compound layer is formed of a titanium compound having a hydrolysable residue and an oilophilic smectite, and has a refractive index higher than the refractive index of the optical material matrix.

3. An optical material comprising:
an optical material matrix; and
a first inorganic compound layer and a second inorganic compound layer which are alternately stacked on the optical material matrix,
wherein the first inorganic compound layer is formed of a titanium compound having a hydrolysable residue and an oilophilic smectite and has a refractive index higher than a refractive index of the optical material matrix, and
wherein the second inorganic compound layer includes silicon oxide and has a refractive index lower than the refractive index of the optical material matrix.

4. The optical material according to claim 3, wherein the second inorganic compound layer is formed of a silicon oxide particle and a silicon compound having a hydrolysable residue.

5. The optical material according to claim 3, wherein the second inorganic compound layer includes a void having a longer axis of 5 to 100 nm.

6. The optical material according to claim 3, wherein the second inorganic compound layer is formed on the outermost surface of the optical material.

7. The optical material according to claim 6, wherein a compound including a perfluoropolyether chain, a perfluoroalkyl chain, or a fluoroalkyl chain is bonded to a surface of the second inorganic compound layer formed on the outermost surface.

8. The optical material according to claim 7, wherein the perfluoropolyether chain, the perfluoroalkyl chain, or the fluoroalkyl chain is bonded to the surface of the second inorganic compound layer by using
[F{CF(CF₃)—CF₂O}ₙ—CF(CF₃)]—X—Si(OR)₃,
{F(CF₂CF₂CF₂O)}—X—Si(OR)₃,
(RO)₃Si—X—{(CF₂CF₂O)ₘ(CF₂O)ₙ}—X—Si(OR)₃,
{H(CF₂)ₙ}—Y—Si(OR)₃, and
{F(CF₂)ₙ}—Y—Si(OR)₃.
(wherein X represents a bond part between the perfluoropolyether chain and an alkoxysilane residue, Y represents a bond part between the perfluoroalkyl chain or the fluoroalkyl chain and the alkoxysilane residue, R represents an alkyl residue, and m and n represent the number of repetition.)

9. The optical material according to claim 3, wherein the optical material matrix comprises a substantially transparent organic resin, an organic substance including silicon, and/or an organic substance.

10. The optical material according to claim 3, wherein the second inorganic compound layer of the first and second inorganic compound layers which are alternatively stacked is placed just above a surface of the optical material matrix, and
a reflecting layer made of aluminum, silver, or chromium is provided on a surface opposite to the surface of the optical material matrix on which the first and second inorganic compound layers are stacked.

11. The optical material according to claim 3, wherein the first inorganic compound layer of the first and second inorganic compound layers which are alternatively stacked is placed just above at least one of surfaces of the optical material matrix in a display surface member for a lens, a prism, a dichroic mirror, a polarization converter, a display device, a vessel of a lamp, a mirror, or a display apparatus.

12. A projection type display apparatus comprising a light source having a lamp and a reflector, a display device, a dichroic-cross-prism, a dichroic mirror, and a mirror, for reflecting a pencil of light from the light source with the mirror, emitting the reflected pencil of light, modulating the light intensity of the emitted pencil of light from the light source with the display device, and enlarging and displaying the modulated image light with a lens, wherein at least one of the reflector, the dichroic mirror, and the mirror is formed of the optical material according to claim 3, and the first inorganic compound layer of the first and second inorganic compound layers which are alternatively stacked is placed just above the optical material matrix.

13. A projection type display apparatus comprising a light source having a lamp and a reflector, a display device, a lens, a polarization converter, a dichroic-cross-prism, a dichroic mirror, and a mirror, for reflecting a pencil of light from the light source with the mirror, emitting the reflected pencil of light, modulating the light intensity of the emitted pencil of light from the light source with the display device, and enlarging and displaying the modulated image light with a lens, wherein at least one of the lens, the polarization converter, the dichroic mirror, the display device, the dichroic-cross-prism, a vessel of the lamp is formed of the optical material according to claim 3, and the first inorganic compound layer of the first and second inorganic compound layers which are alternatively put is placed just above the optical material matrix.

14. The projection type display apparatus according to claim 13, further comprising a screen for projecting the image light from a back face, wherein the screen is formed of the optical material according to claim 3, and the first and second inorganic compound layers are stacked on a front face.

15. A light conduction system comprising a means for letting in external light, a light-guide tube for guiding the taken external light, and a light-exit part for exiting the guided external light, wherein the light-guide tube is formed of the optical material according to claim 3, and the second inorganic compound layer of the first and second inorganic compound layers which are alternatively stacked is placed just above the optical material matrix.

16. The light conduction system according to claim 15, further comprising a reflecting layer formed of aluminum or silver provided on a surface opposite to a surface of the optical material matrix on which the first and second inorganic compound layers are stacked.

17. A greenhouse comprising at least one transparent wall surface, wherein the transparent wall surface is formed of the optical material according to claim 3, and the first inorganic compound layer of the first and second inorganic compound layers which are alternatively stacked is placed just above the optical material matrix.

18. A solar energy converting device at least comprising an insulating transport plate, a surface electrode, a photon-electron converter, a middle transport electrode, and a back electrode, wherein the insulating transport plate is formed of the optical material according to claim 3, and the first inorganic compound layer of the first and second inorganic compound layers which are alternatively stacked is placed just above the optical material matrix.

19. A backlight unit for a liquid crystal display comprising a light-emitting layer and a reflecting layer, wherein the reflecting layer is formed of the optical material according to claim 3, and the second inorganic compound layer of the first and second inorganic compound layers is placed just above the optical material matrix.
